(19) United States
(12) Patent Application Publication
(10) Pub. No.: US 2010/0225000 A1
(43) Pub. Date: Sep. 9, 2010

(54) SEMICONDUCTOR DEVICE AND METHOD OF MANUFACTURING SEMICONDUCTOR DEVICE

(75) Inventors: Yoshiaki Sugizaki, Kanagawa (JP); Akihiro Kojima, Kanagawa (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/699,301

(22) Filed: Feb. 3, 2010

(30) Foreign Application Priority Data
Mar. 6, 2009 (JP) 2009-054012

(51) Int. Cl. H01L 23/522; H01L 21/768

(52) U.S. Cl. 257/773; 438/113; 257/E23.142; 257/E21.575

(57) ABSTRACT

A semiconductor device includes a semiconductor substrate including a wiring layer; electrode pads that are not provided on, above and below with the semiconductor substrate and are provided to be electrically connected with wiring lines included in the wiring layer; and a resin layer that is fixed to the semiconductor substrate and supports the electrode pads.

### CROSS-REFERENCE TO RELATED APPLICATIONS

This application is based upon and claims the benefit of priority from the prior Japanese Patent Application No. 2009-054012, filed on Mar. 6, 2009; the entire contents of which are incorporated herein by reference.

### BACKGROUND OF THE INVENTION

Semiconductor chips have been mounted at high density in accordance with the request for the high-performance and downsizing of a portable information terminal, a storage device, or the like. There is a method of laminating semiconductor chips as a method of mounting the semiconductor chips at high density. In this case, there is a method of electrically connecting semiconductor chips through via holes that are formed at semiconductor substrates, with advantages that there is no limit on the number of chips to be laminated or the size of the chip at the time of laminating semiconductor chips (Japanese Patent Application Laid-Open (JP-A) No. 2007-53149).

### BRIEF SUMMARY OF THE INVENTION

A semiconductor device according to an embodiment of the present invention comprises: a semiconductor substrate including a wiring layer; electrode pads that are not provided on, above and below with the semiconductor substrate and are provided to be electrically connected with wiring lines included in the wiring layer; and a resin layer that is fixed to the semiconductor substrate and supports the electrode pads.

A semiconductor device according to an embodiment of the present invention comprises: a semiconductor substrate including a wiring layer; electrode pads that are provided so as to protrude laterally from the sides of the semiconductor substrate and are formed to be electrically connected with wiring lines included in the wiring layer; and resin layers that are fixed to the semiconductor substrate so as to protrude laterally from the sides of the semiconductor substrate and supports the electrode pads; and through holes or grooves that are provided so as to pass through the electrode pads in a vertical direction, and pass through the resin layers in the vertical direction.

A method of manufacturing a semiconductor device according to an embodiment of the present invention comprises: forming a wiring layer, which includes an electrode pad, on a semiconductor substrate of a semiconductor wafer that is divided into chip regions; forming an inorganic insulating film above the semiconductor wafer; removing the inorganic insulating film that is formed on the electrode pad and a scribe line of the semiconductor wafer; forming a first resin layer above the upper surface of the semiconductor wafer, on which the inorganic insulating film is laminated; forming a first opening through which a part of the upper surface of the electrode pad is exposed from the first resin layer; removing the semiconductor substrate below the electrode pad by selectively etching the lower surface of the semiconductor substrate; exposing the electrode pad from a lower surface; forming a second resin layer on the lower surface of the semiconductor wafer with; forming a second opening through which a part of the lower surface of the electrode pad is exposed from the second resin layer, and forming a third opening through which the lower surface of the first resin layer corresponding to the scribe line is exposed to the outside; and cutting the first resin layer and cutting the second resin layer along the scribe line.

### BRIEF DESCRIPTION OF THE DRAWINGS

FIGS. 1A, 1B, 1C, and 1D are perspective views illustrating a method of manufacturing a semiconductor device according to a first embodiment;

FIGS. 2A, 2B, 2C, and 2D are perspective views illustrating a modification of the method of manufacturing the semiconductor device illustrated in FIGS. 1A, 1B, 1C, and 1D;

FIGS. 3A, 4A, 5A, 6A, 7, 8, 9A, 10A, 11A, 12A, 13A, 14, and 15 are cross-sectional views each illustrating a method of manufacturing a semiconductor device according to a second embodiment;

FIGS. 3B, 4B, 5B, and 6B are plan views each illustrating the method of manufacturing the semiconductor device according to the second embodiment;

FIGS. 9B, 10B, 11B, 12B, and 13B are bottom views each illustrating the method of manufacturing the semiconductor device according to the second embodiment;

FIG. 16 is a cross-sectional view illustrating a method of manufacturing a semiconductor device according to a third embodiment;

FIG. 17 is a cross-sectional view illustrating a method of manufacturing a semiconductor device according to a fourth embodiment;

FIGS. 18A, 18B, 18C, 18D and 18E are views illustrating a method of manufacturing a semiconductor device according to a fifth embodiment;

FIG. 19A is a perspective view schematically showing the configuration of a semiconductor device according to a sixth embodiment, and FIG. 19B is a perspective view showing a modification of the semiconductor device of FIG. 19A;

FIGS. 20A, 21A, 22, 23, 24A, 25A, 26A, 27A, 28A, and 29 are cross-sectional views each illustrating a method of manufacturing a semiconductor device according to a seventh embodiment;

FIGS. 20B and 21B are plan views each illustrating the method of manufacturing the semiconductor device according to the seventh embodiment;

FIGS. 24B, 25B, 26B, 27B, and 28B are bottom views each illustrating the method of manufacturing the semiconductor device according to the seventh embodiment;

FIG. 30A is a perspective view schematically showing the configuration of a semiconductor device according to an eighth embodiment, and FIG. 30B is a perspective view showing a modification of the semiconductor device of FIG. 30A;

FIG. 31A is a cross-sectional view illustrating a method of manufacturing a semiconductor device according to a ninth embodiment of the invention, and FIG. 31B is a bottom view illustrating the method of manufacturing the semiconductor device according to the ninth embodiment;

FIG. 32A is a perspective view schematically showing the configuration of a semiconductor device according to a tenth embodiment, and FIG. 32B is a perspective view showing a modification of the semiconductor device of FIG. 32A;

FIGS. 33A, 34, 35, 36A, 37A, 38A, 39A, 40A, and 41 are cross-sectional views each illustrating a method of manufacturing a semiconductor device according to an eleventh embodiment;

FIG. 33B is a plan view illustrating the method of manufacturing the semiconductor device according to the eleventh embodiment;

FIGS. 368, 37B, 38B, 39B, and 40B are bottom views each illustrating the method of manufacturing the semiconductor device according to the eleventh embodiment;

FIG. 42A is a perspective view schematically showing the configuration of a semiconductor device according to a twelfth embodiment, and FIG. 42B is a perspective view showing a modification of the semiconductor device of FIG. 42A;

FIGS. 43A, 44A, 45, 46, 47A, 48A, 49A, 50A, and 51A are cross-sectional views each illustrating a method of manufacturing a semiconductor device according to a thirteenth embodiment;

FIGS. 43B and 44B are plan views each illustrating the method of manufacturing the semiconductor device according to the thirteenth embodiment;

FIGS. 47B, 48B, 49B, 50B, and 51B are bottom views each illustrating the method of manufacturing the semiconductor device according to the thirteenth embodiment;

FIGS. 52A, 52B, and 52C are views illustrating a method of manufacturing a semiconductor device according to a fourteenth embodiment;

FIGS. 53A, 53B, and 53C are views showing a modification of the method of manufacturing the semiconductor device of FIGS. 52A, 52B, and 52C;

FIGS. 54A, 54B, and 54C are views illustrating a method of manufacturing a semiconductor device according to a fifteenth embodiment;

FIGS. 55A, 55B, and 55C are views showing a modification of the method of manufacturing the semiconductor device of FIGS. 54A, 54B, and 54C;

FIGS. 56A, 56B, and 56C are views illustrating a method of manufacturing a semiconductor device according to a sixteenth embodiment;

FIGS. 57A, 57B, and 57C are views showing a modification of the method of manufacturing the semiconductor device of FIGS. 56A, 56B, and 56C;

FIGS. 58A, 58B, and 58C are views illustrating a method of manufacturing a semiconductor device according to a seventeenth embodiment; and

FIGS. 59A, 59B, and 59C are views showing a modification of the method of manufacturing the semiconductor device of FIGS. 58A; 58B, and 58C.

### DETAILED DESCRIPTION

In a method disclosed in JP-A No. 2007-53149, through holes smaller than electrode pads are formed at a semiconductor substrate in order to electrically connect semiconductor chips that are laminated in a vertical direction. Accordingly, when the semiconductor chips are connected, stress is applied to the semiconductor substrate or an interlayer insulating film formed on the semiconductor substrate, which causes cracks of the semiconductor substrate or the interlayer insulating film. For this reason, there may be a problem in that the reliability of a semiconductor device deteriorates.

Semiconductor devices and methods of manufacturing the semiconductor devices according to embodiments of the invention will be described below with reference to drawing. Meanwhile, the invention is not limited to these embodiments.

### First Embodiment

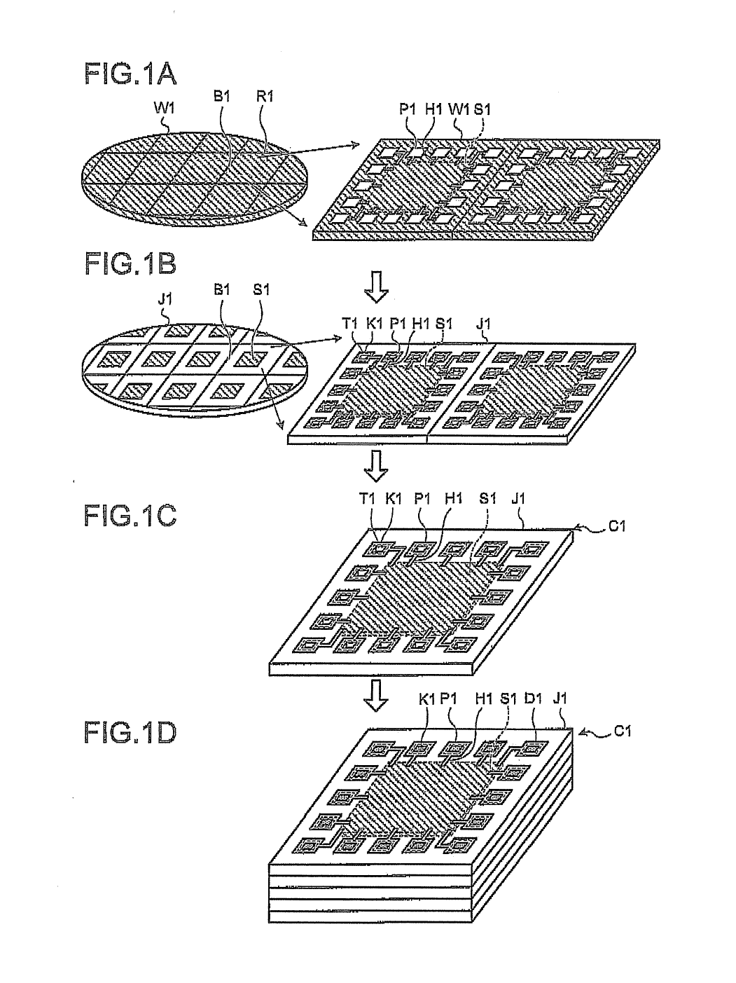

FIGS. 1A, 1B, 1C, and 1D are perspective views illustrating a method of manufacturing a semiconductor device according to a first embodiment of the invention.

In FIGS. 1A, 1B, 1C, and 1D, a semiconductor wafer W1 is divided into chip regions R1 by scribe lines B1. A wiring layer, which is formed on a semiconductor substrate S1, is formed in each of the chip regions R1 on the semiconductor wafer W1. Wiring lines H1, which are formed integrally with electrode pads P1, are formed on the wiring layer. Here, the electrode pads P1 and the wiring lines H1 are disposed on the same plane. Further, the uppermost wiring line of the wiring lines, which are formed on the wiring layer, may be used as the wiring line H1. Wiring lines may be formed below the wiring line H1 on the wiring layer.

Meanwhile, for example, Si, Ge, SiGe, GaAs, InP, GaP, GaN, SiC, GaInAsP, and the like may be used as a material of the semiconductor substrate S1. Further, a field-effect transistor may be formed in each of the chip regions R1. Alternatively, a flash memory, a DRAM, a microcomputer, a logic circuit, an image sensor, or the like may be formed in each of the chip regions. Furthermore, it is preferable that the electrode pads P1 be disposed at the peripheral portion of each of the chip regions R1 and be particularly disposed outside the wiring lines H1. Further, an insulating layer may be formed on the wiring layer, which is formed on the semiconductor substrate S1, in order to insulate the semiconductor substrate S1 from the wiring lines H1. In this case, an inorganic material, such as a silicon oxide film or a silicon nitride film, may be used as the insulating layer formed on the wiring layer.

Further, if the semiconductor substrate S1 below the electrode pads P1 is removed along the scribe lines B1 in each of the chip regions R1 while the semiconductor substrate S1 remains inside the electrode pads P1, the electrode pads P1 are disposed not to interfere with the semiconductor substrate S1. In this case, examples of a form where the electrode pads P1 are disposed not to interfere with the semiconductor substrate S1 may include a form where the electrode pads P1 are disposed so as to protrude from the sides of the semiconductor substrate S1.

Further, a resin layer J1 is formed in the region of the semiconductor wafer W1 where the semiconductor substrate S1 is removed, and is fixed to the semiconductor substrate S1 separated into each chip region R1; Accordingly, the electrode pads P1 protruding from the sides of the semiconductor substrate S1 are supported by the resin layer, and the semiconductor substrates S1 separated into the respective chip regions R1 are integrally supported by the resin layer. In this case, the semiconductor substrate Si separated into each chip region R1 may be embedded in the resin layer J1 so that at least a part of the electrode pads P1 are exposed to the outside. For example, polyimide, BCB (benzocyclobutene), PBO (polybenzoxazole), epoxy, or an organic material such as phenol may be used as the material of the resin layer J1. Further, it is preferable that the resin layer J1 have thermoplasticity. Furthermore, before the resin layer J1 is formed around the semiconductor substrate S1 separated into each chip region R1, the semiconductor substrate S1 may be thinned.

Further, an opening K1 is formed at each of the electrode pads P1, and through holes T1, which pass through the resin layer J1 in a vertical direction, are formed at the resin layer J1. In this case, the through holes T1 may be disposed so as to pass through the electrode pads P1 through the openings K1 in the vertical direction, respectively. Meanwhile, it is preferable that the openings K1 and the through holes T1 be formed while the semiconductor substrates S1 separated into the respective chip regions R1 are integrally supported by the resin layer J1.

Further, a semiconductor chip C1 where the resin layer J1 is disposed so as to surround the periphery of the semiconductor substrate S1 is cut by cutting the resin layer J1 along the scribe lines B1. In this case, the electrode pads P1 are disposed so as to protrude from the sides of the semiconductor substrate S1, and are supported on the resin layer J1 that is disposed so as to surround the periphery of the semiconductor substrate S1. Further, the surface of the resin layer J1 on which the electrode pads P1 are disposed may be formed to continue to the surface of the semiconductor substrate S1 on which the wiring lines H1 are disposed.

Furthermore, the semiconductor chips C1 are laminated so that the electrode pads P1 overlap each other in the vertical direction, and the upper and lower electrode pads P1 are electrically connected to each other by embedding a conductor D1 in the through holes T1. Accordingly, the semiconductor chips C1, which are laminated in the vertical direction, are electrically connected to each other. Meanwhile, for example, a conductive paste may be used as the conductor D1, and a plating material may be used as the conductor. Further, a method of connecting the semiconductor chips C1 by using the thermoplasticity of the resin layer J1 or a method of forming an adhesive layer between the semiconductor chips C1 may be used as a method of connecting the laminated semiconductor chips C1.

Accordingly, it may be possible to reduce the stress that is applied to the semiconductor substrate S1 or an inorganic insulating film formed on the semiconductor substrate at the time of connecting the semiconductor chips C1. Even when the semiconductor substrate S1 is thinned, it may be possible to prevent cracks from being generated in the semiconductor substrate S1 or the inorganic insulating film.

Further, the through holes T1 are formed at the resin layer J1, so that it may be possible to electrically connect the upper and lower electrode pads P1 without forming through holes at the semiconductor substrate S1 of the semiconductor chip C1. For this reason, it is not necessary to form an insulating film on the side surface of the through hole of the semiconductor substrate S1 or to form an opening through which the electrode pad is exposed to the outside at the insulating film, and it may be possible to simplify the structure for electrically connecting the upper and lower electrode pads P1.

Furthermore, since the semiconductor substrates S1, which are separated into the respective chip regions R1 along the scribe lines B1, are integrally Supported by the resin layer J1, only the resin layer J1 may be cut at the time of cutting the semiconductor chip C1 and it is not necessary to cut the semiconductor substrate S1 or an inorganic insulating film formed on the semiconductor substrate. For this reason, it may be possible to prevent the cutting chips of the semiconductor substrate S1 or the inorganic insulating film, which is formed on the semiconductor substrate, from being attached to the surface of the semiconductor substrate S1 due to the scattering of the cutting chips to the surroundings at the time of cutting the semiconductor chip C1.

Meanwhile, in order to reduce the connection failure between the conductor D1 and the electrode pad P1, it is preferable that the size of the through hole T1 be more increased than the size of the opening K1 and a part of the lower surface of the electrode pad P1 be exposed from the resin layer J1.

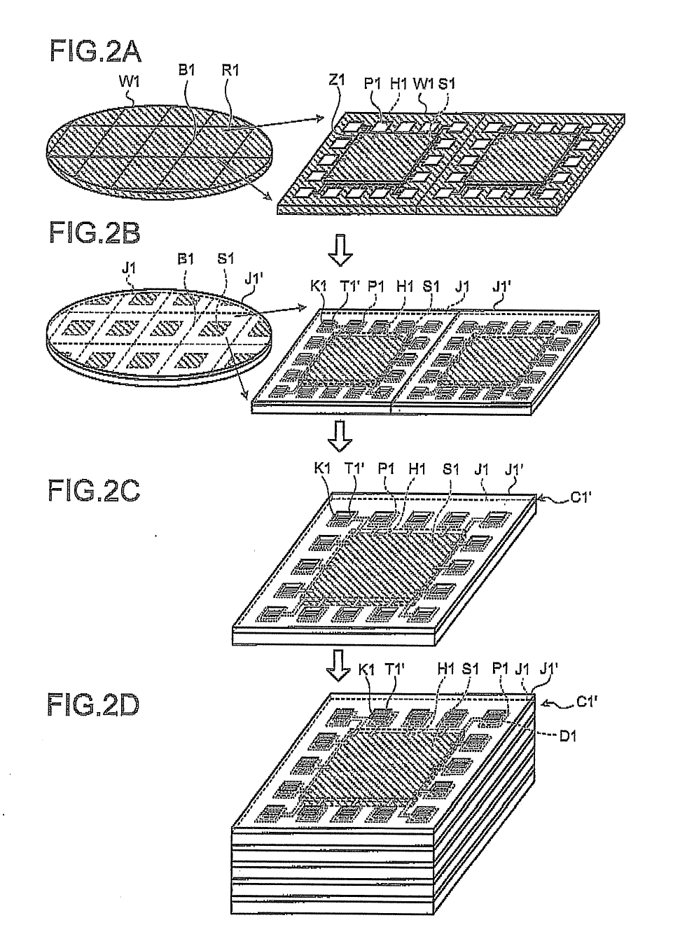

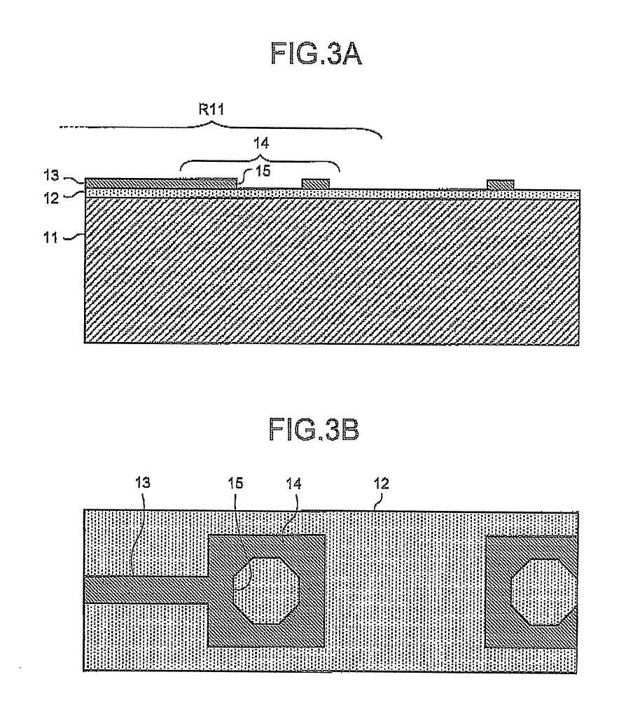

Meanwhile, in the above-mentioned embodiment, there is no limit on the upper surfaces of the electrode pad P1 and the wiring line H1. However, an insulating film may be laminated on the upper surfaces of the electrode pad and the wiring line. For example, as shown in FIGS. 2A, 2B, 2C, and 2D, an inorganic insulating film Z1 may be laminated on the semiconductor substrate S1 and a resin layer J1′ may be further laminated on the inorganic insulating film. In this case, a silicon oxide film, a silicon nitride film, a laminated film thereof, or the like may be used as the inorganic insulating film Z1. Polyimide, BCB (benzocyclobutene), PBO (polybenzoxazole), epoxy, phenol, or the like may be used as the resin layer J1′. If openings larger than the electrode pads P1 are formed at the inorganic insulating film Z1 so that the entire upper surface of the electrode pad P1 is exposed from the inorganic insulating film Z1, it may be possible to prevent cracks from being generated in the inorganic insulating film Z1, which is a brittle material, when the semiconductor chips C1 are laminated so that the electrode pads P1 are connected to each other.

Meanwhile, if through holes T1′, which are smaller than the electrode pads P1 and larger than the openings K1 of the electrode pads P1, are formed at the resin layer J1′, the outer peripheries of the electrode pads P1 are fixed, and a part of the upper surfaces of the electrode pads P1 and the openings K1 are exposed, the positions of the electrode pads P1 may be fixed. Further, when semiconductor chins C1′ are laminated so that the electrode pads P1 overlap each other in the vertical direction, the semiconductor chips may be electrically connected to each other by the embedment of the conductor D1.

In addition, if the inorganic insulating film Z1 is opened along the scribe lines B1 and the resin layer J1′ is not opened on the scribe lines B1, the chip regions R1 may be fixed to predetermined positions on the semiconductor wafer W1, it is not necessary to cut the inorganic insulating film Z1 at the time of cutting the semiconductor chip C1 from the semiconductor wafer W1, and it may be possible to prevent cutting chips from being attached to the surface of the semiconductor chip C1′ due to the scattering of the cutting chips. Further, when the scribe lines B1 are fixed by the resin layer J1′ formed on the upper surface, it is not necessary to fix the scribe lines B1 by the resin layer J1 formed on the lower surface. Accordingly, it may be possible to make the portions of the resin layer J1, which are below the scribe lines B1, simultaneously open by a photolithography process for forming the through holes T1. Meanwhile, if having thermoplasticity, at least one of the resin layer J1′ and the resin layer J1 may be used as an adhesive layer at the time of lamination.

### Second Embodiment

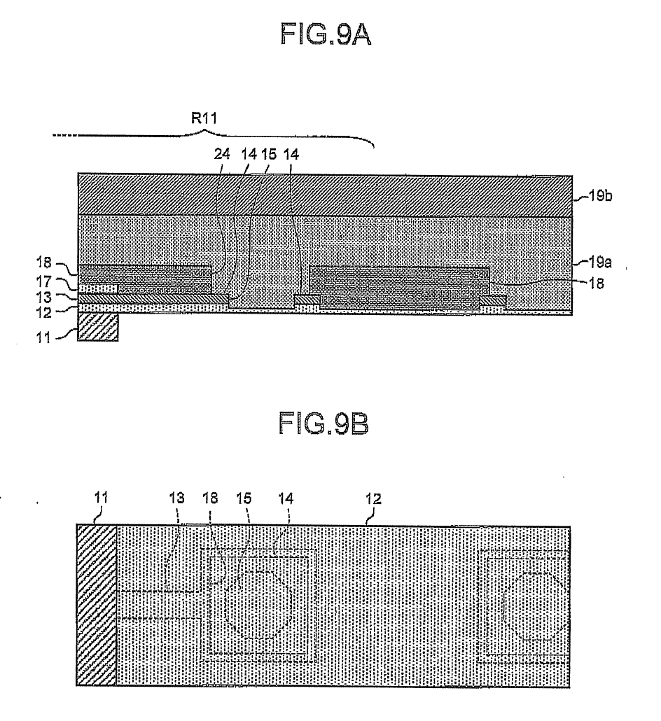

FIGS. 3A to 6A, 7, 8, 10A to 13A, 14, and 15 are cross-sectional views illustrating a method of manufacturing a semiconductor device according to a second embodiment of the invention. FIGS. 3B to 6B are plan views illustrating the method of manufacturing the semiconductor device according to the second embodiment of the invention. FIGS. 9B to 13B are bottom views illustrating the method of manufacturing the semiconductor device according to the second embodiment of the invention.

In FIGS. 3A and 3B, an insulating layer 12′is formed on a semiconductor substrate 11, and wiring lines 13 formed integrally with electrode pads 14 are formed on the insulating layer 12. In this case, an opening 15 is formed at each of the electrode pads 14.

Further, before being cut into individual pieces, the semiconductor substrate 11 is formed in the shape of a wafer and divided into chip regions R11. In this case, a lower wiring layer may be formed on the semiconductor substrate 11 below the insulating layer 12. Furthermore, a field-effect transistor may be formed in each of the chip regions R11 on the semiconductor substrate 11. Alternatively, a flash memory, a DRAM, a microcomputer, a logic circuit, an image sensor, or the like may be formed in each of the chip regions. An inorganic insulating film, such as a silicon oxide film or a silicon nitride film, may be used as the insulating layer 12. Alternatively, a laminated structure where a silicon nitride film is laminated on a silicon oxide film may be used. Further, the thickness of the whole of the insulating layer 12 and the wiring line 13 may be set in the range of, for example, 1 to 10 μm.

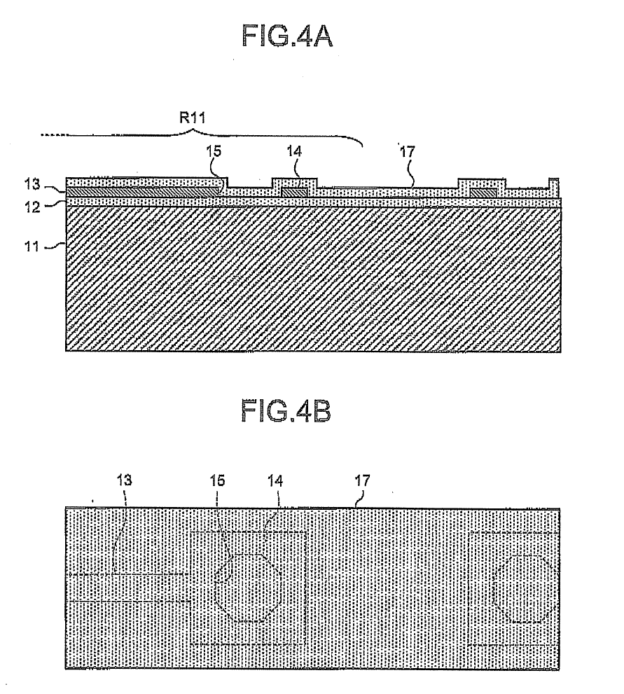

Then, as shown in FIGS. 4A and 4B, a passivation film 17 is formed on the wiring lines 13 and the electrode pads 14 by a CVD method or the like. Meanwhile, an inorganic insulating film, such as a silicon oxide film or a silicon nitride film, may be used as the passivation film 17.

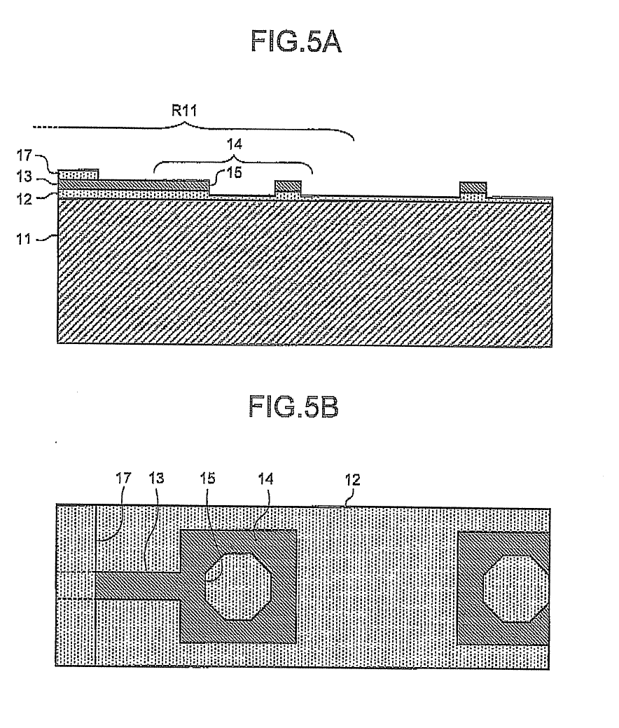

After that, as shown FIGS. 5A and 5B, the passivation film 17 corresponding to the entire outer peripheral portions of the chip regions R11 is removed by using a photolithography technique and a dry etching technique, and the electrode pads 14 are exposed from the passivation film 17. In this case, it is preferable that the passivation film 17 corresponding to scribe regions between the chip regions R11 also be removed when the passivation film 17 corresponding to the entire cuter peripheral portions of the chip regions R11 is removed.

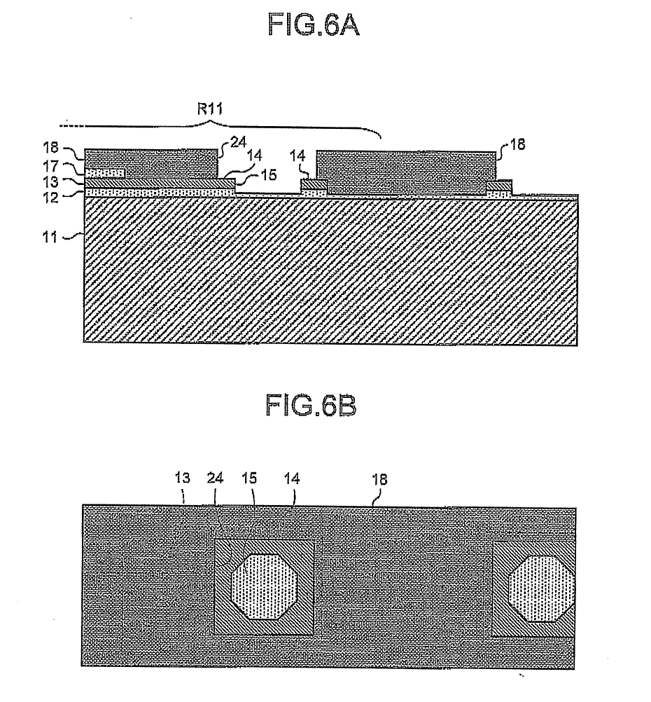

Then, as shown in FIGS. 6A and 6B, a resin layer 18 is formed on the semiconductor substrate 11. For example, polyimide, BCB (benzocyclobutene), PBO (polybenzoxazole), epoxy, or an organic material such as phenol may be used as the material of the resin layer 18. Further, it is preferable that the resin layer 18 have photosensitivity. Furthermore, the thickness of the resin layer 18 may be set to, for example, about 3 μm.

In this case, a spin coating method or a method of bonding a resin film to the semiconductor substrate 11 may be used as a method of forming the resin layer 18 on the semiconductor substrate 11.

Further, through holes 24 through which the electrode pads 14 are exposed to the outside are formed at the resin layer 18. Meanwhile, it is preferable that the through hole 24 be disposed inside the outer periphery of the electrode pad 14. Furthermore, it is preferable that the resin layer 18 remain in the scribe regions between the chip regions R11.

In this case, if the resin layer 18 has photosensitivity, a method of exposing the resin layer 18 to light and developing the resin layer may be used as a method of forming the through holes 24 at the resin layer 18. Further, if the resin layer 18 does not have photosensitivity, a photolithography technique and an etching technique may be used as the method of forming the through holes. Meanwhile, when a wafer level test is performed, an electrode pad for a wafer level test may also be opened simultaneously.

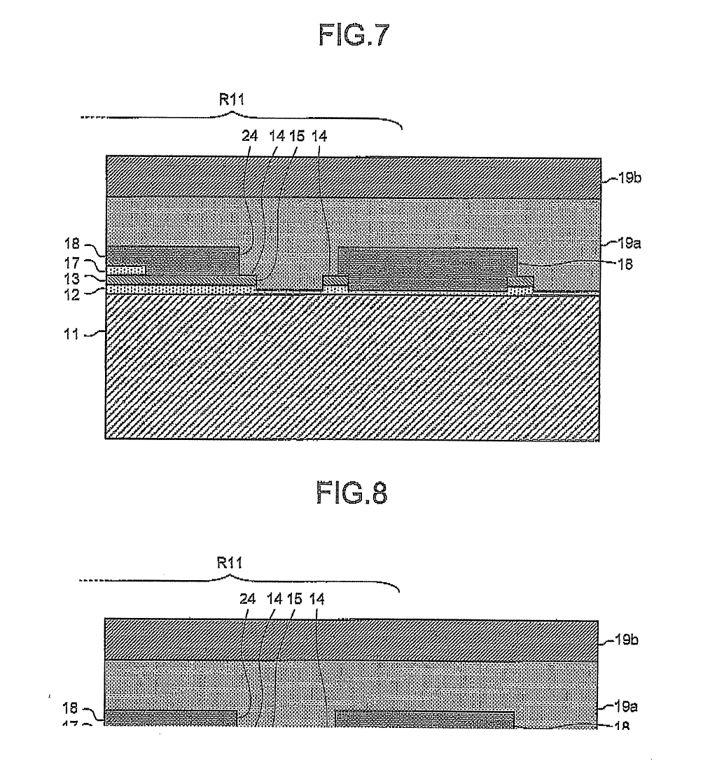

Then, as shown in FIG. 7, a protective sheet 19a and a protective plate 19b, which support the semiconductor substrate 11 during the grinding of the lower surface of the semiconductor substrate 11, are formed on the resin layer 18. Meanwhile, an adhesive resin sheet, which can be detached from the semiconductor substrate 11 after being attached to the semiconductor substrate 11, may be used as the protective sheet 19a. Alternatively, an ultraviolet curable resin or the like may be used as the protective sheet so as to be easily detached from the semiconductor substrate 11 after being attached to the semiconductor substrate 11. Further, an organic material may be used as the protective plate 19b, and a wafer made of silicon or glass may be used.

After that, as shown in FIG. 8, the semiconductor substrate 11 is thinned by grinding the lower surface of the semiconductor substrate 11. Meanwhile, the thickness of the thinned semiconductor substrate 11 may be set in the range of, for example, 5 to 10 μm. Further, it is preferable that mirror finishing be performed on the lower surface of the semiconductor substrate 11 by CMP (chemical mechanical planarization) or the like after mechanical grinding is performed when the semiconductor substrate 11 is thinned.

Subsequently, as shown in FIGS. 9A and 9B, the semiconductor substrate 11 corresponding to the entire outer peripheral portions of the chip regions R11 is removed by using a photolithography technique and a dry etching technique, and the lower surface of the insulating layer 12 below the electrode pads 14 is exposed from the semiconductor substrate 11. In this case, it is preferable that the semiconductor substrate 11 corresponding to scribe regions between the chip regions R11 also be removed when the semiconductor substrate 11 corresponding to the entire outer peripheral portions of the chip regions R11 is removed.

Accordingly, it may be possible to separate the semiconductor substrates 11 into the respective chip regions R11, and to dispose the electrode pads 14 so that the electrode pads protrude from the sides of the semiconductor substrate 11. Further, since the semiconductor substrate 11 corresponding to the scribe regions between the chip regions R11 is also removed, it may be possible to prevent the semiconductor substrate 11 from being cut in a dicing process and to prevent the cutting chips of the semiconductor substrate 11 from being scattered to the surroundings.

Meanwhile, when a resist pattern is formed on the lower surface of the semiconductor substrate 11 by a photolithography technique, it may be possible to detect alignment marks, which are formed on the upper surface of the semiconductor substrate 11, by making the semiconductor substrate 11 transmit infrared light in order to align the position of the resist pattern formed on the lower surface of the semiconductor substrate 11 with the pattern formed on the upper surface of the semiconductor substrate 11. Alternatively, deep holes may be formed on the upper surface of the semiconductor substrate 11 as the alignment marks so that the alignment marks are exposed to the lower surface of the semiconductor substrate 11 when the semiconductor substrate 11 is thinned.

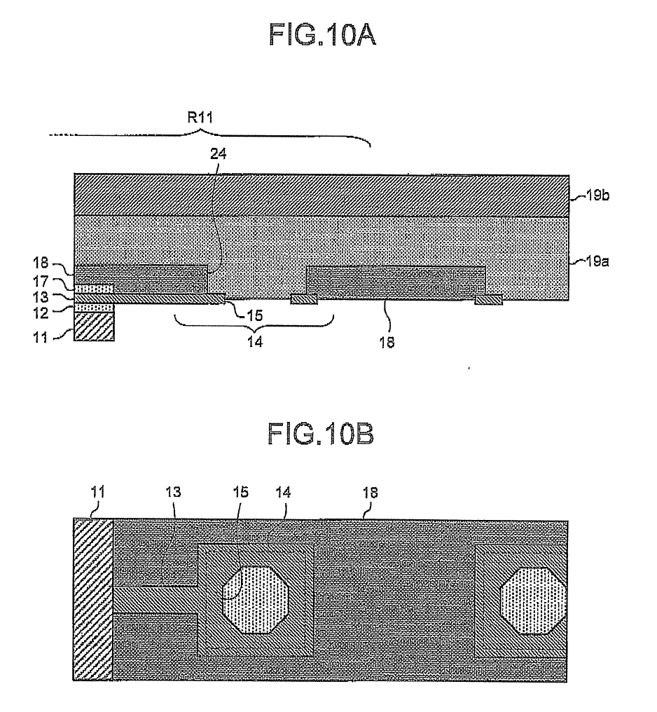

After that, as shown FIGS. 10A and 10B, the insulating layer 12 corresponding to the entire outer peripheral portions of the chip regions R11 is removed by etching the insulating layer 12 while the semiconductor substrate 11 is used as a mask, and the lower surfaces of the electrode pads 14 are exposed from the semiconductor substrate 11. In this case, it is preferable that the insulating layer 12 corresponding to scribe regions between the chip regions R11 also be removed when the insulating layer 12 corresponding to the entire outer peripheral portions of the chip regions R11 is removed.

Meanwhile, it is preferable that RIE (reactive ion etching) be used in order to prevent side etching when the insulating layer 12 is etched while the semiconductor substrate 11 is used as a mask.

In this case, if abnormal plasma discharge occurs when the RIE is used and the lower surfaces of the electrode pads 14 are exposed to the outside, a laminated structure where a silicon nitride film is laminated on a silicon oxide film may be used as the insulating layer 12. Further, the lower surfaces of the electrode pads 14 may be exposed to the outside by removing the silicon nitride film by CDE (chemical dry etching) after the silicon oxide film is removed by the RIE.

Meanwhile, when the insulating layer 12 corresponding to the entire outer peripheral portions of the chip regions R11 is removed, a photolithography process may be added and a resist pattern may be used as a mask other than a method of using the semiconductor substrate 11 as a mask. In this case, etching is performed at the end of the insulating layer 12 that protrudes from the semiconductor substrate 11. Accordingly, even though the side etching is performed during the etching of the insulating layer 12, an undercut-shaped portion is not formed below the semiconductor substrate 11. Therefore, wet etching may be used for the etching of the insulating layer 12 in addition to the RIE.

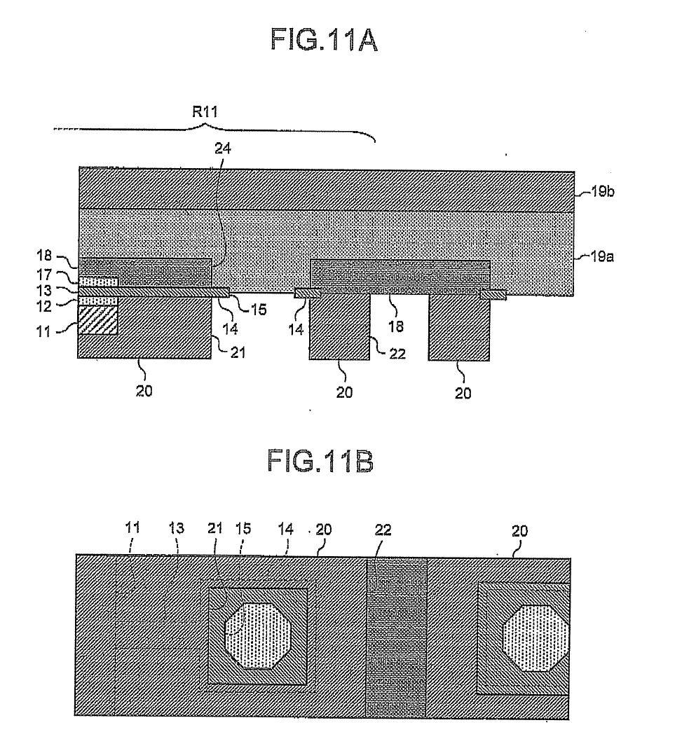

After that, as shown in FIGS. 11A and 11B, a resin layer 20 is formed on the lower surface of the semiconductor substrate 11. Meanwhile, for example, polyimide, BCB (benzocyclobutene), PBC (polybenzoxazole), epoxy, or an organic material such as phenol may be used as the material of the resin layer 20. Further, it is particularly preferable that the resin layer 20 have thermoplasticity. Further, it is particularly preferable that the resin layer 20 have photosensitivity. Furthermore, the thickness of the resin layer 20 may be set to, for example, about 3 μm.

In this case, a spin coating method or a method of bonding a resin film to the semiconductor substrate 11 may be used as a method of forming the resin layer 20 on the lower surface of the semiconductor substrate 11.

Further, through holes 21 through which the lower surfaces of the electrode pads 14 are exposed to the outside are formed at the resin layer 20, and grooves 22 through which the scribe regions between the chip regions R11 are exposed to the outside are formed at the resin layer 20. Meanwhile, it is preferable that the through hole 21 be disposed inside the outer periphery of the electrode pad 14.

In this case, if the resin layer 20 has photosensitivity, a method of exposing the resin layer 20 to light and developing the resin layer may be used as a method of forming the through holes 21 and the grooves 22 at the resin layer 20. Further, if the resin layer 20 does not have photosensitivity, a photolithography technique and an etching technique may be used as the method of forming the through holes.

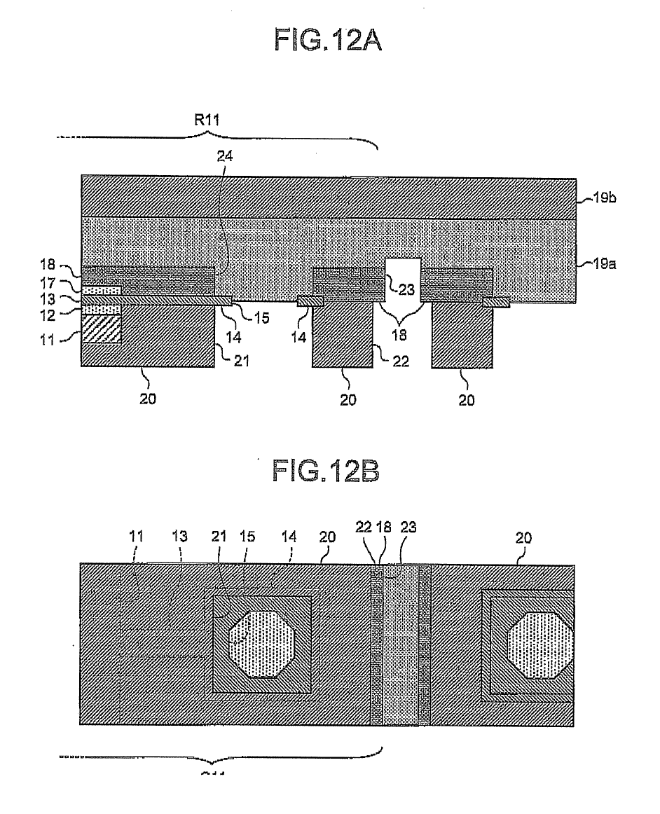

Then, as shown in FIGS. 12A and 12B, the resin layer 18 is cut by forming a groove 23 at the resin layer 18 along the scribe lines between the chip regions R11, and a semiconductor chip C11 where the resin layers 18 and 20 are disposed so as to surround the periphery of the semiconductor substrate 11 is cut. In this case, the electrode pads 14 are disposed so as to protrude from the sides of the semiconductor substrate 11, and are supported by the resin layers 18 and 20 that are disposed so as to surround the periphery of the semiconductor substrate 11.

Further, since the semiconductor substrate 11 or the insulating layer 12 is removed from the scribe region between the chip regions R11, it may be possible to prevent the cutting chips of the semiconductor substrate 11 or the insulating layer 12 from being scattered to the surroundings at the time of cutting the semiconductor chip C11. Meanwhile, a dicing method of cutting the resin layer by blades or a method of cutting the resin layer by laser may be used as a method of cutting the resin layer 18. In addition, in this embodiment, the semiconductor chips C11 are cut while being attached to the protective sheet 19a and the protective plate 19b. However, the semiconductor chips C11 may be cut after being detached from the protective sheet 19a and the protective plate 19b.

Further, it may be possible to balance stress and suppress the generation of the warpage of the semiconductor chip C11 by forming the resin layers 18 and 20 on the upper and lower sides of the semiconductor substrate 11, respectively. Meanwhile, the thickness of the resin layers 18 and 20 may be arbitrarily set so that the warpage is at a minimum by optimizing the balance of stress.

In this case, for example, the thickness of the resin layer 20 is 3 μm, the thickness of the semiconductor substrate 11 is 8 μm, the thickness of the wiring layer formed on the semiconductor substrate 11 is 3 μm, and the thickness of the resin layer 18 is 3 μm, the thickness of the entire semiconductor chip C11 is 17 μm. For this reason, if the thickness of the semiconductor wafer is about 775 μm, it may be possible to set the thickness of the entire semiconductor chip C11 to about 1/50 of the thickness of the semiconductor wafer.

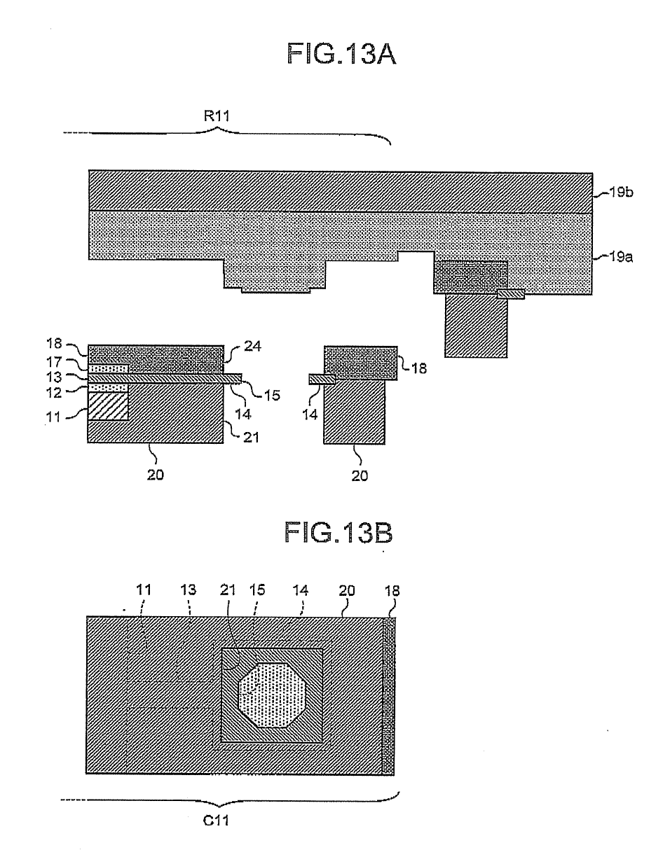

After that, as shown in FIGS. 13A and 13B, the individually cut semiconductor chips C11 are picked up from the protective sheet 19a and the protective plate 19b.

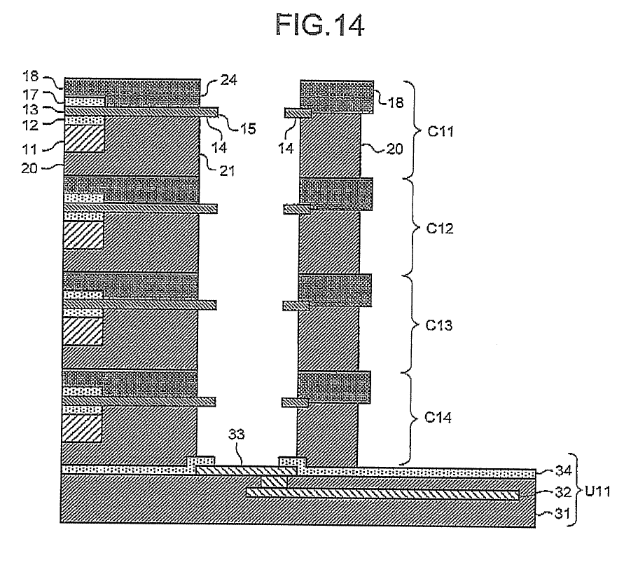

Subsequently, as shown in FIG. 14, while the resin layer 20 is heated, semiconductor chips C11 to C14 are sequentially laminated on a mounting substrate U11 so that the electrode pads 14 overlap each other in the vertical direction. Meanwhile, each of the semiconductor chips C12 to C14 may be formed to have the same structure as the semiconductor chip C11. In this case, the mounting substrate U11 includes an insulating substrate 31, and wiring lines 32 and electrode pads 33 connected to the wiring lines 32 axe formed on the insulating substrate 31. Further, a passivation film 34, which is disposed so as to expose the electrode pads 33 to the outside, is formed on the insulating substrate 31.

If the resin layers 20 have thermoplasticity when the semiconductor chips C11 to C14 are fixed to each other, it may be possible to attach the semiconductor chips by heating the resin layers 20. Meanwhile, if the resin layers 20 do not have thermoplasticity, an adhesive may be used. In this case, if an adhesive is used, an adhesive layer may be previously formed on the lower surface of the resin layer 20 before the semiconductor chips C11 are individually cut. Alternatively, the resin layers 18 may have thermoplasticity. In this case, the semiconductor chips C11 to C14 are turned upside down and laminated so that the resin layer 18 faces downward in contrast to FIG. 14.

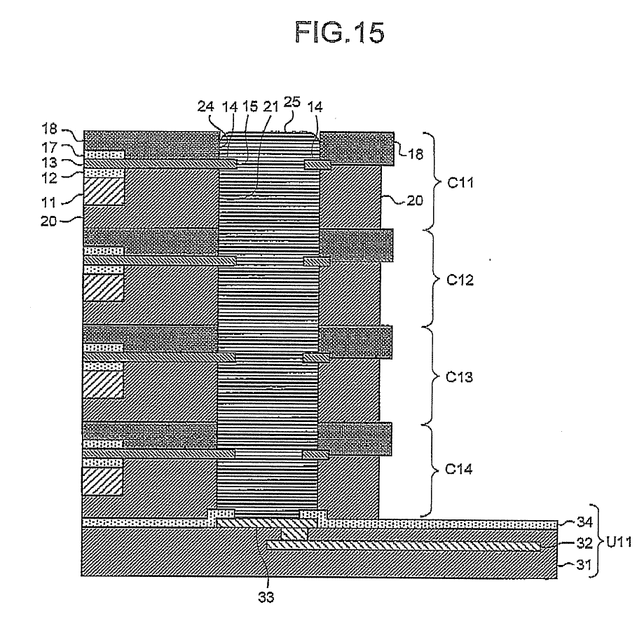

After that, as shown in FIG. 15, a conductor 25 is embedded in the through holes 21 and 24, so that the upper and lower electrode pads 14 are electrically connected to each other. Accordingly, the semiconductor chips C11 to C14, which are laminated in the vertical direction, are electrically connected to each other. Meanwhile, for example, a conductive paste may be used as the conductor 25, and a plating material may be used as the conductor. Further, an ink jet method may be used when a conductive paste is embedded in the through holes 21 and 24. It is preferable that the conductive paste contains nanoparticles of noble metal such as gold, silver, or copper or contain molten metal such as solder.

Furthermore, in order to facilitate the electrical connection with the conductive paste, it is preferable that the surfaces of the electrode pads 14 and 33 be coated with gold or palladium. Moreover, it may be possible to form the conductor 25 on the electrode pads 33 by electrolytic plating while the wiring lines 32 are used as plating wires.

In this case, it may be possible to reduce the stress, which is applied to the semiconductor substrate 11, the insulating layer 12, or the passivation film 17 at the time of connecting the upper and lower electrode pads 14, by forming the resin layer 20 around the semiconductor substrate 11 and supporting the electrode pads 14, which protrude from the sides of the semiconductor substrate 11, by the resin layer 20. For this reason, even when the semiconductor substrate 11 is thinned, it may be possible to prevent cracks from being generated in the semiconductor substrate 11, the insulating layer 12, or the passivation film 17.

Meanwhile, the method of forming the resin layer 18 even on the semiconductor substrate 11 has been described in the above-mentioned second embodiment. However, the resin layer 18 may not be formed on the semiconductor substrate 11.

### Third Embodiment

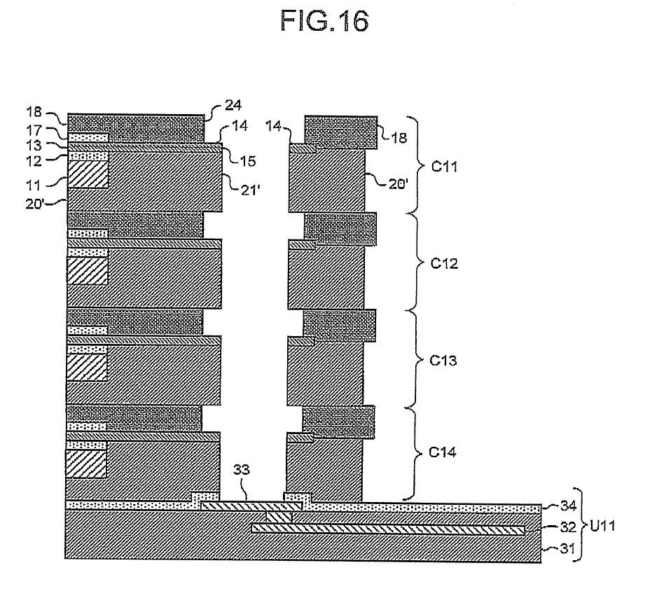

FIG. 16 is a cross-sectional view illustrating a method of manufacturing a semiconductor device according to a third embodiment of the invention.

The method of forming the through holes 24 and 21 at the resin layers 18 and 20, respectively, so that the lower surfaces of the electrode pads 14 are exposed to the outside has been described in the embodiment of FIG. 14. However, in FIG. 16, a resin layer 20′ is formed instead of the resin layer 20 and through holes 21′ may be formed at the resin layer 20′ so that only the upper surfaces of the electrode pads 14 are exposed to the outside.

### Fourth Embodiment

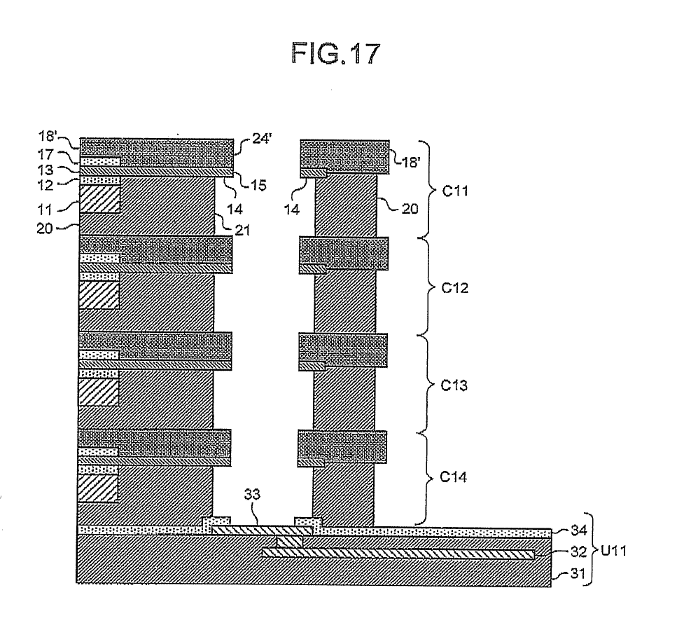

FIG. 17 is a cross-sectional view illustrating a method of manufacturing a semiconductor device according to a fourth embodiment of the invention.

The method of forming the through holes 24 and 21 at the resin layers 18 and 20, respectively, so that the upper and lower surfaces of the electrode pads 14 are exposed to the outside has been described in the embodiment of FIG. 14. However, in FIG. 17, a resin layer 18′ is formed instead of the resin layer 18 and through holes 24′ may be formed at the resin layer 18′ so that only the lower surfaces of the electrode pads 14 are exposed to the outside.

### Fifth Embodiment

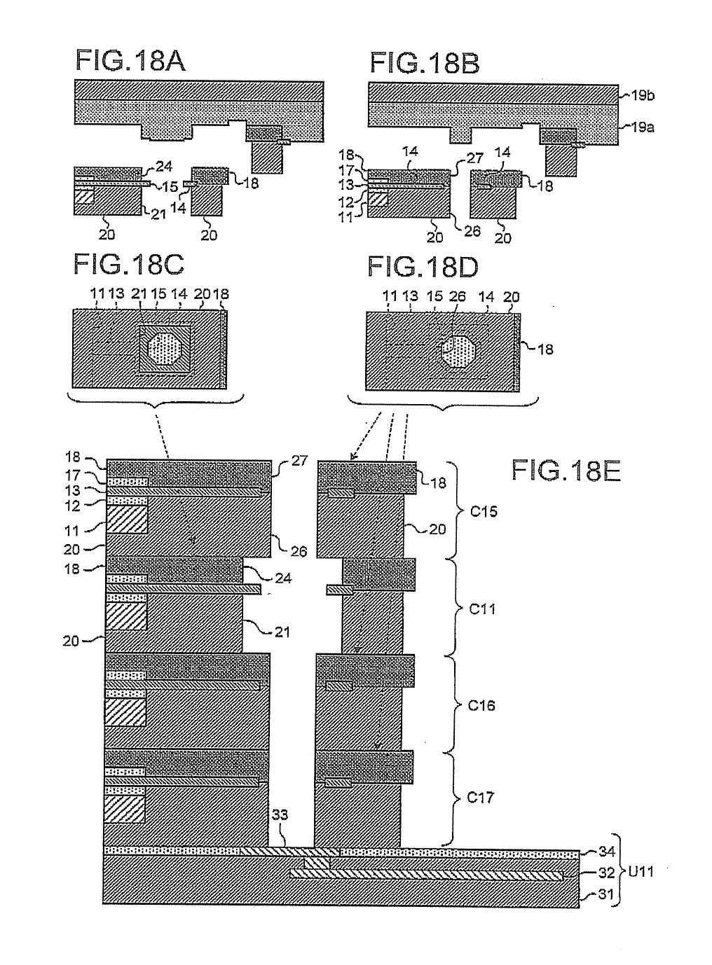

FIGS. 18A, 18B, 18C, 18D and 18E are views illustrating a method of manufacturing a semiconductor device according to a fifth embodiment of the invention.

In FIGS. 18A, 18B, 18C, 18D and 18E, through holes 27 and 26 are formed at the resin layers 18 and 20 of semiconductor chips C15 to C17, respectively, instead of the through holes 24 and 21 that are formed at the resin layers 18 and 20 of the semiconductor chips C11, respectively.

In this case, if the electrode pad 14 is used as a chip select terminal of a memory chip, the through holes 27 and 26 may be formed so that the electrode pads 14 are not exposed from the resin layers 18 and 20.

Further, the semiconductor chips C11 and C15 to C17 are laminated on the mounting substrate U11 so that the electrode pads 14 overlap each other in the vertical direction. Furthermore, it may be possible to electrically connect only the electrode pads 14 of the semiconductor chips C11 to the electrode pads 33 of the mounting substrate U11 and to select the chip by embedding a conductor in the through holes 21, 24, 26, and 27.

### Sixth Embodiment

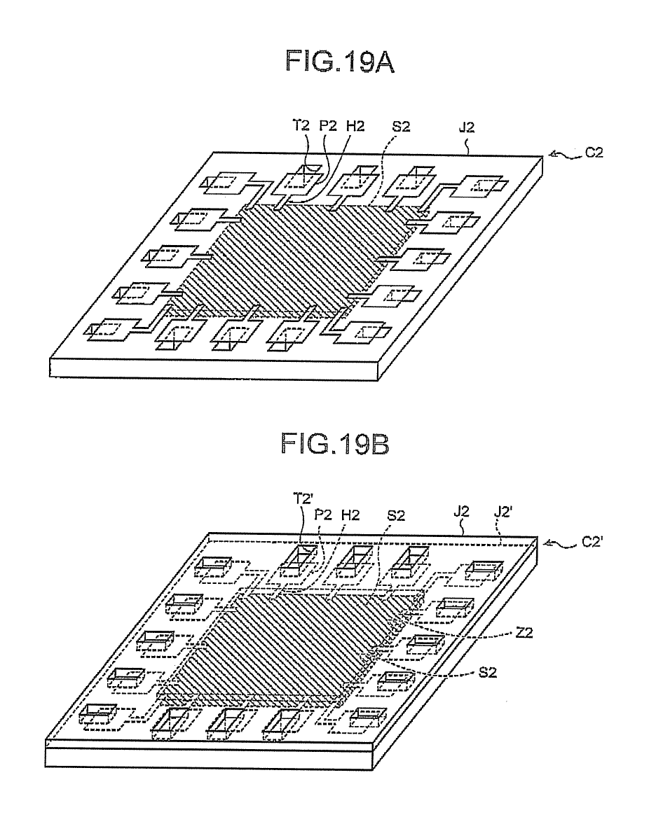

FIG. 19A is a-perspective view schematically showing the configuration of a semiconductor device according to a sixth embodiment of the invention, and FIG. 19B is a perspective view showing a modification of the semiconductor device of FIG. 19A.

In FIG. 19A, a semiconductor chip C2 includes a semiconductor substrate S2. Further, a wiring layer is formed on the semiconductor substrate S2, and electrode pads P2 formed integrally with wiring lines H2 are formed at the wiring layer. In this case, the electrode pads P2 are disposed on the same plane as the wiring lines H2 so as to protrude from the sides of the semiconductor substrate S2.

Further, a resin layer J2 is formed on the semiconductor chip C2. In this case, the resin layer J2 is fixed to the semiconductor substrate S2 so as to protrude from the sides of the semiconductor substrate S2. Furthermore, the resin layer J2 is disposed so as to support the electrode pads P2 from below and surround the periphery of the semiconductor substrate S2. Moreover, the surface of the resin layer J2 on which the electrode pads P2 are disposed may be formed to continue to the surface of the semiconductor substrate S2 on which the wiring lines H2 are disposed.

Further, through holes T2, which pass through the resin layer J2 in the vertical direction, are formed at the resin layer J2. In this case; since the through holes T2 may be disposed so as to extend over the ends of the electrode pads P2, a part of the lower surfaces of the electrode pads P2 are exposed from the resin layer J2. Furthermore, the semiconductor chips C2 are laminated and a conductor is embedded in the through holes T2, so that the semiconductor chips C2, which are laminated in the vertical direction, may be electrically connected to each other.

Accordingly, it may be possible to make a conductor flow into the through holes T2 of the semiconductor chips C2, which are laminated in the vertical direction, without forming openings at the electrode pads P2, and to electrically connect the semiconductor chips C2 that are laminated in the vertical direction.

Further, it may be possible to reduce the stress that is applied to the semiconductor substrate S2 or an inorganic insulating film formed on the semiconductor substrate at the time of connecting the semiconductor chips C2. Even when the semiconductor substrate S2 is thinned, it may be possible to prevent cracks from being generated in the semiconductor substrate S2 or the inorganic insulating film.

Meanwhile, in the above-mentioned embodiment, there is no limit on the upper surfaces of the electrode pad P2 and the wiring line H2. However, an insulating film may be laminated on the upper surfaces of the electrode pad and the wiring line. For example, as shown in FIG. 19B, an inorganic insulating film Z2 may be laminated on the semiconductor substrate S2 and a resin layer J2′ may be further laminated on the inorganic insulating film. In this case, a silicon oxide film, a silicon nitride film, a laminated film thereof, or the like may be used as the inorganic insulating film Z2. Polyimide, BCB (benzocyclobutene), PBO (polybenzoxazole), epoxy, phenol, or the like may be used as the resin layer J2′. In this case, openings larger than the electrode pads P2 are formed at the inorganic insulating film Z2, so that the entire upper surface of the electrode pad P2 is exposed from the inorganic insulating film Z2. Meanwhile, since through holes T2′ may be formed at the resin layer J2′ so as to extend over the ends of the electrode pads P2, the positions of the electrode pads P2 may be fixed. Further, when semiconductor chips C2′ are laminated so that the electrode pads P2 overlap each other in the vertical direction, the semiconductor chips may be electrically connected to each other by the embedment of a conductor. Meanwhile, if having thermoplasticity, at least one of the resin layer J2′ and the resin layer J2 may be used as an adhesive layer at the time of lamination.

### Seventh Embodiment

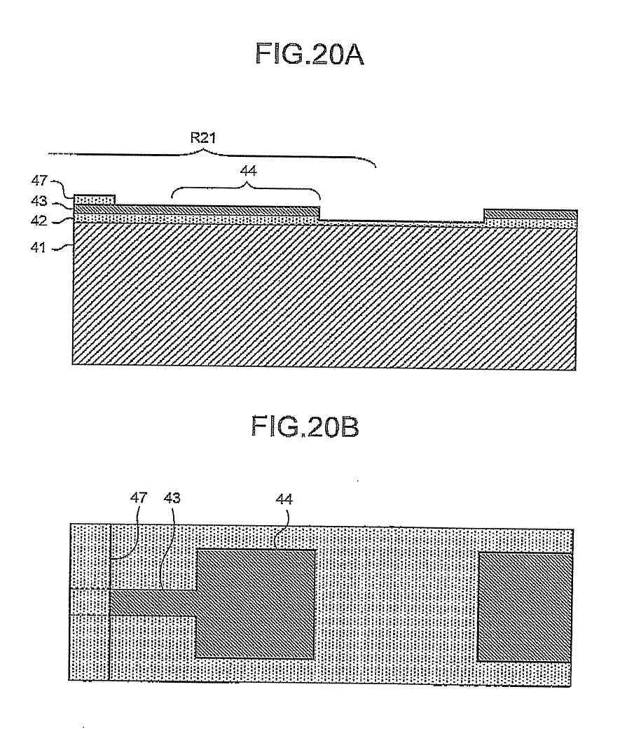

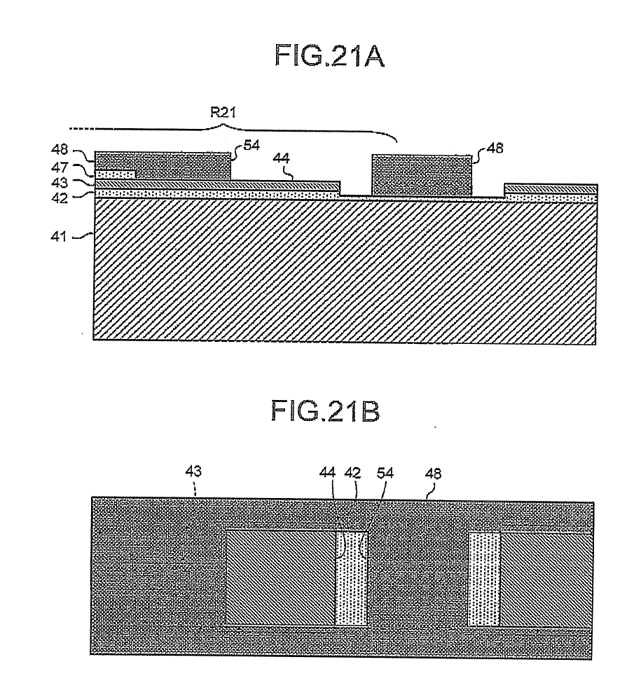

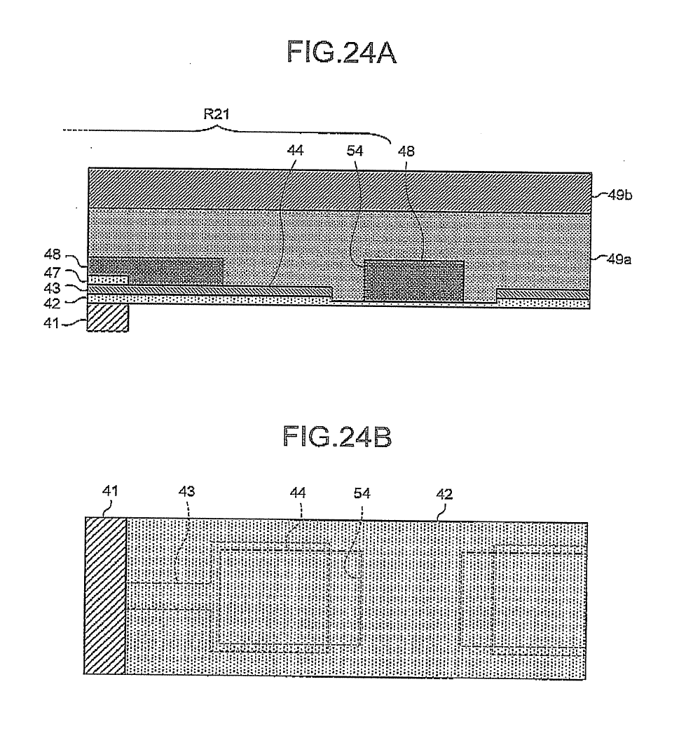

FIGS. 20A, 21A, 22, 23, 24A to 28A, and 29 are cross-sectional views illustrating a method of manufacturing a semiconductor device according to a seventh embodiment of the invention. FIGS. 20B and 21B are plan views illustrating the method of manufacturing the semiconductor device according to the seventh embodiment of the invention. FIGS. 24B to 28B are bottom views illustrating the method of manufacturing the semiconductor device according to the seventh embodiment of the invention.

In FIGS. 20A and 20B, a passivation film 47 corresponding to the entire outer peripheral portions of chip regions R21 is removed by the same processes as those of FIGS. 3A to 5A and 3B to 5B, and electrode pads 44 are exposed from the passivation film 47. In this case, it is preferable that the passivation film 47 corresponding to scribe regions between the chip regions R21 also be removed when the passivation film 47 corresponding to the entire outer peripheral portions of the chip regions R21 is removed.

Meanwhile, an insulating layer 42 is formed on a semiconductor substrate 41, and the electrode pads 44 and wiring lines 43 are formed on the insulating layer 42. In this case, the electrode pads 44 are formed integrally with the wiring lines 43. In the embodiment shown in FIGS. 5A and 5B, the opening 15 is formed at the electrode pad 14. However, in the embodiment shown in FIGS. 20A and 20B, an opening is not formed at the electrode pad 44.

After that, as shown in FIGS. 21A and 21B, a resin layer 48 is formed on the semiconductor substrate 41. Further, through holes 54 through which the electrode pads 44 are exposed to the outside are formed at the resin layer 48. Meanwhile, it is preferable that the through hole 54 be disposed so as to extend over the end of the electrode pad 44. Furthermore, it is preferable that the resin layer 48 remain in the scribe regions between the chip regions R21.

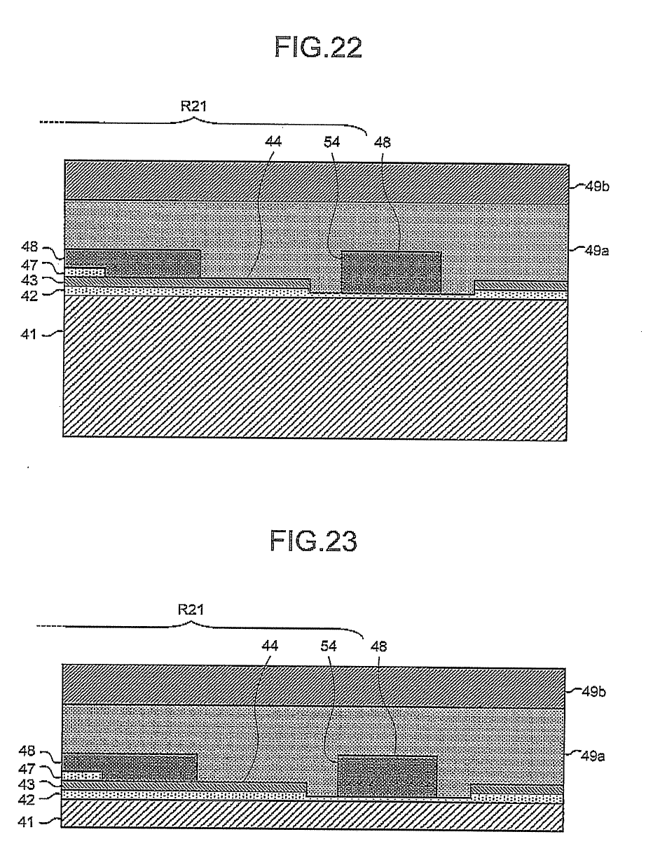

Then, as shown in FIG. 22, a protective sheet 49a and a protective plate 49b, which support the semiconductor substrate 41 during the grinding of the lower surface of the semiconductor substrate 41, are formed on the resin layer 48.

After that, as shown in FIG. 23, the semiconductor substrate 41 is thinned by grinding the lower surface of the semiconductor substrate 41.

Subsequently, as shown in FIGS. 24A and 24B, the semiconductor substrate 41 corresponding to the entire outer peripheral portions of the chip regions R21 is removed by using a photolithography technique and a dry etching technique, and the lower surface of the insulating layer 42 below the electrode pads 44 is exposed from the semiconductor substrate 41. In this case, it is preferable that the semiconductor substrate 41 corresponding to scribe regions between the chip regions R21 also be removed when the semiconductor substrate 41 corresponding to the entire outer peripheral portions of the chip regions R21 is removed.

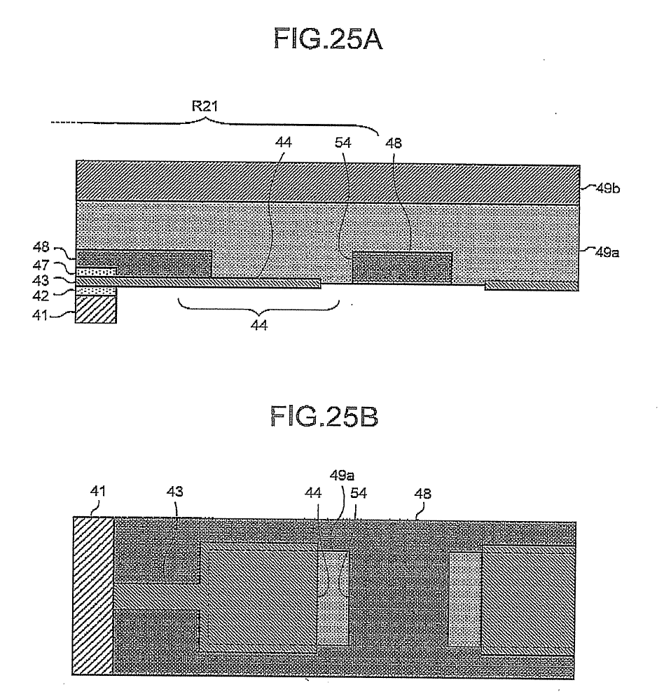

After that, as shown FIGS. 25A and 25B, the insulating layer 42 corresponding to the entire outer peripheral portions of the chip regions R21 is removed by etching the insulating layer 42 while the semiconductor substrate 41 is used as a mask, and the lower surfaces of the electrode pads 44 are exposed from the semiconductor substrate 41. In this case, it is preferable that the insulating layer 42 corresponding to scribe regions between the chip regions R21 also be removed when the insulating layer 42 corresponding to the entire outer peripheral portions of the chip regions R21 is removed.

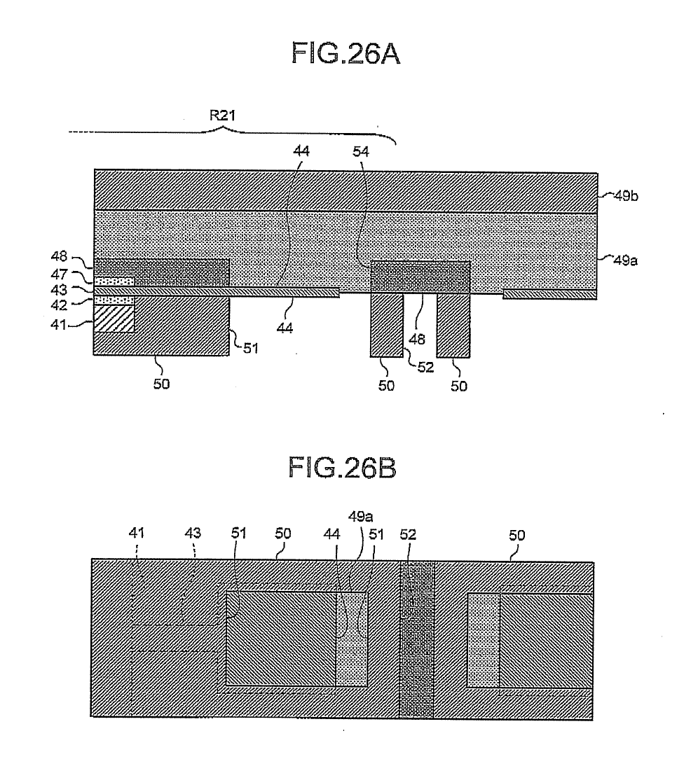

Then, as shown in FIGS. 26A and 26B, a resin layer 50 is formed on the lower surface of the semiconductor substrate 41. Further, through holes 51 through which the lower surfaces of the electrode pads 44 are exposed to the outside are formed at the resin layer 50, and grooves 52 through which the scribe regions between the chip regions R21 are exposed to the outside are formed at the resin layer 50. Meanwhile, it is preferable that the through hole 51 be disposed so as to extend over the end of the electrode pad 44.

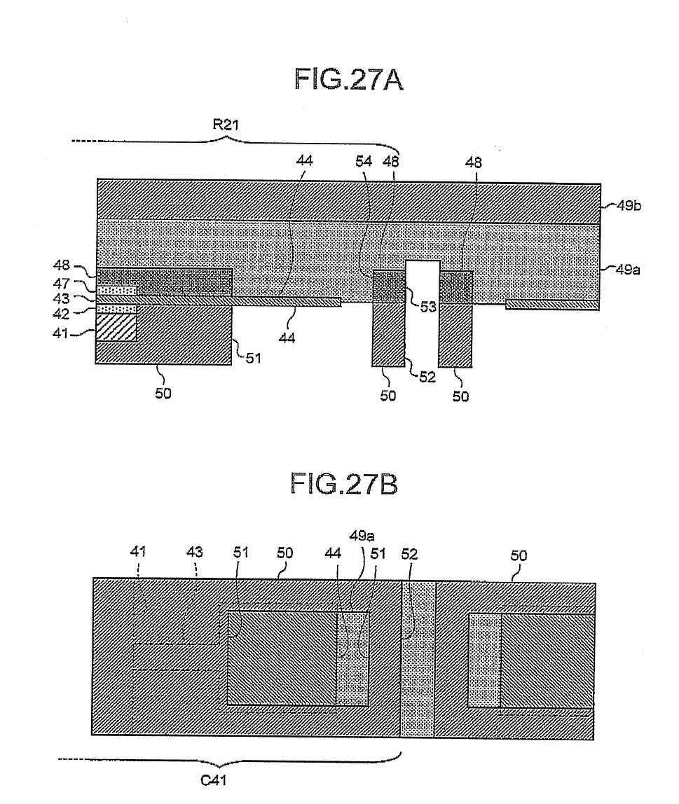

After that, as shown in FIGS. 27A and 27B, the resin layer 48 is cut by forming a groove 53 at the resin layer 48 along the scribe lines between the chip regions R21, and a semiconductor chip C41 where the resin layers 48 and 50 are disposed so as to surround the periphery of the semiconductor substrate 41 is cut. In this case, the electrode pads 44 are disposed so as to protrude from the sides of the semiconductor substrate 41, and are supported by the resin layers 48 and 50 that are disposed so as to. surround the periphery of the semiconductor substrate 41.

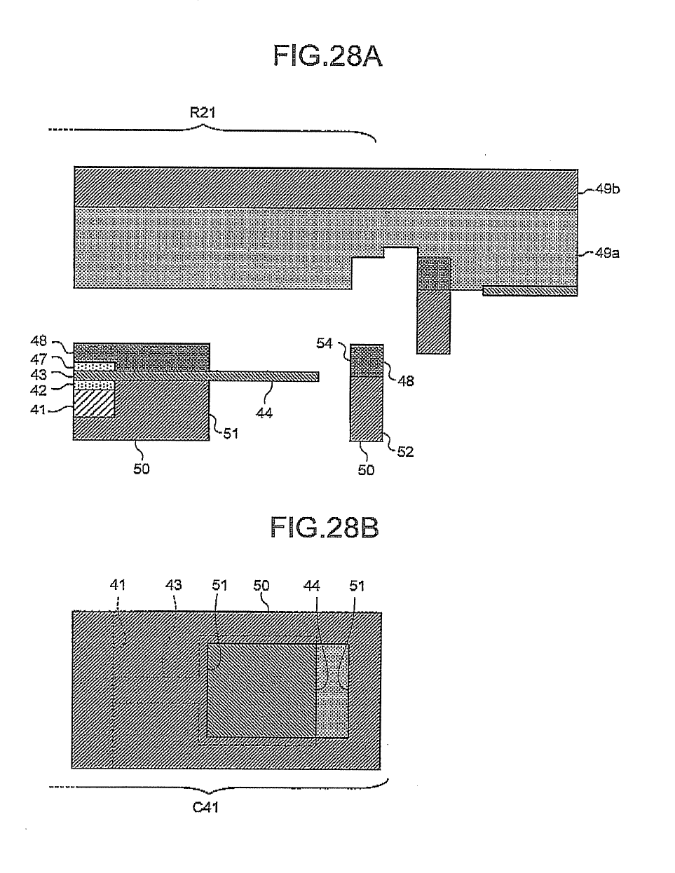

Then, as shown in FIGS. 28A and 28B, the individually cut semiconductor chips C41 are picked up from the protective sheet 49a and the protective plate 49b.

Meanwhile, in this embodiment, the semiconductor chips C41 are cut while being attached to the protective sheet 49a and the protective plate 49b. However, the semiconductor chips C41 may be cut after being detached from the protective sheet 49a and the protective plate 49b.

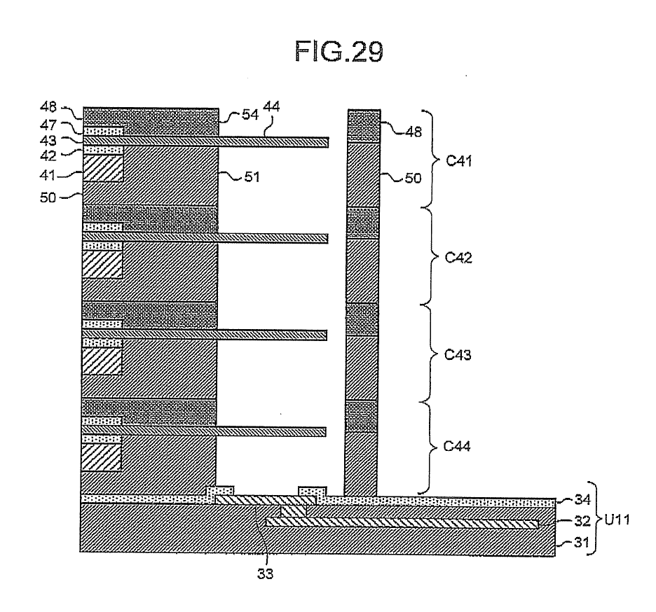

Subsequently, as shown in FIG. 29, while the resin layer 50 is heated, semiconductor chips C41 to C44 are sequentially laminated on a mounting substrate U11 so that the electrode pads 44 overlap each other in the vertical direction. Further, a conductor is embedded in the through holes 51 and 54, so that the upper and lower electrode pads 44 are electrically connected to each other and the semiconductor chips C41 to C44, which are laminated in the vertical direction, are electrically connected to each other. Meanwhile, each of the semiconductor chips C42 to C44 may be formed to have the same structure as the semiconductor chip C41.

Accordingly, it may be possible to reduce the stress, which is, applied to the semiconductor substrate 41, the insulating layer 42, or the passivation film 47 at the time of connecting the upper and lower electrode pads 44. For this reason, even when the semiconductor substrate 41 is thinned, it may be possible to prevent cracks from being generated in the semiconductor substrate 41, the insulating layer 42, or the passivation film 47.

### Eighth Embodiment

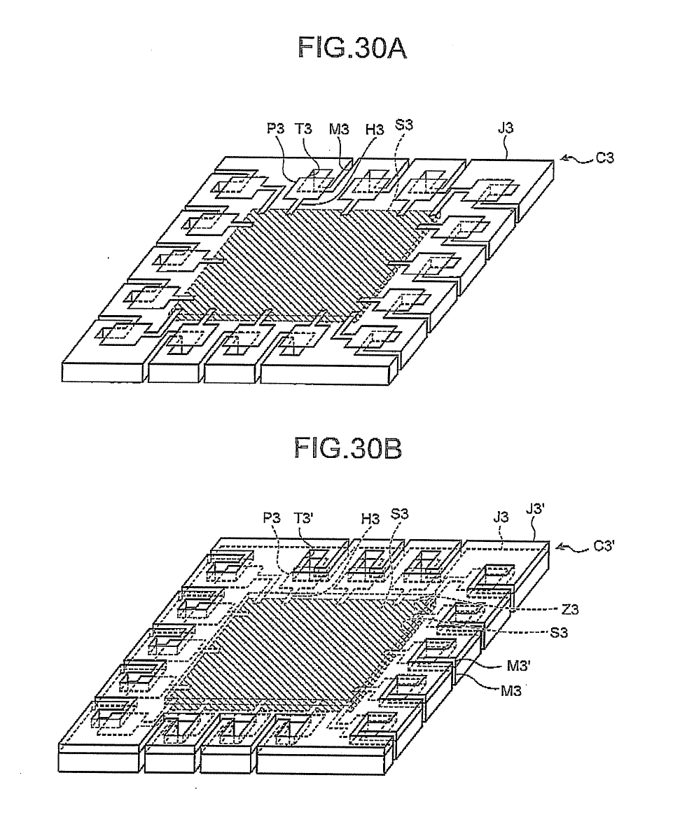

FIG. 30A is a perspective view schematically showing the configuration of a semiconductor device according to an eighth embodiment of the invention, and FIG. 30B is a perspective view showing a modification of the semiconductor device of FIG. 30A.

In FIG. 30A, a semiconductor chip C3 includes a semiconductor substrate S3. Further, a wiring layer is formed on the semiconductor substrate S3, and electrode pads P3 formed integrally with wiring lines H3 are formed at the wiring layer. In this case, the electrode pads P3 are disposed on the same plane as the wiring lines H3 so as to protrude from the sides of the semiconductor substrate S3.

Further, a resin layer J3 is formed on the semiconductor chip C3. In this case, the resin layer J3 is fixed to the semiconductor substrate S3 so as to protrude from the sides of the semiconductor substrate S3. Furthermore, the resin layer J3 is disposed so as to support the electrode pads P3 from below and surround the periphery of the semiconductor substrate S3. Moreover, the surface of the resin layer J3 on which the electrode pads P3 are disposed may be formed to continue to the surface of the semiconductor substrate S3 on which the wiring lines H3 are disposed.

Further, through holes T3, which pass through the resin layer J3 in the vertical direction, are formed at the resin layer J3. In this case, since the through holes T3 may be disposed so as to extend over the ends of the electrode pads P3, a part of the lower surfaces of the electrode pads P3 are exposed from the resin layer J3. Furthermore, grooves M3, which communicate with the through hole T3, are formed on the side surfaces of the resin layer J3 so as to correspond to the through holes T3, respectively. Moreover, the semiconductor chips C3 are laminated and a conductor is embedded in the through holes J3, so that the semiconductor chips C3, which are laminated in the vertical direction, may be electrically connected to each other.

Accordingly, it may be possible to make a conductor flow into the through holes T3 of the semiconductor chips C3, which are laminated in the vertical direction, without forming openings at the electrode pads P3, and to electrically connect the semiconductor chips C3 that are laminated in the vertical direction.

Further, since the grooves M3, which communicate with the through holes T3, are formed on the side surfaces of the resin layer J3, it may be possible to make a conductor flow into the through holes T3 while air existing in the through holes T3 is let out from the grooves M3. Even when a plurality of semiconductor chips C3 is laminated in the vertical direction, it may be possible to reduce the electrical connection failure between the semiconductor chips C3.

Furthermore, it may be possible to reduce the stress that is applied to the semiconductor substrate S3 or an inorganic insulating film formed on the semiconductor substrate at the time of connecting semiconductor chips C3. Even when the semiconductor substrate S3 is thinned, it may be possible to prevent cracks from being generated in the semiconductor substrate S3 or the inorganic insulating film.

Meanwhile, in the above-mentioned embodiment, there is no limit on the upper surfaces of the electrode pad P3 and the wiring line H3. However, an insulating film may be laminated on the upper surfaces of the electrode pad and the wiring line. For example, as shown in FIG. 30B, an inorganic insulating film Z3 may be laminated on the semiconductor substrate S3 and a resin layer J3′ may be further laminated on the inorganic insulating film. In this case, a silicon oxide film, a silicon nitride film, a laminated film thereof, or the like may be used as the inorganic insulating film Z3. Polyimide, BCB (benzocyclobutene), PBO (polybenzoxazole), epoxy, phenol, or the like may be used as the resin layer J3′. In this case, openings larger than the electrode pads P3 are formed at the inorganic insulating film Z3, so that the entire upper surface of the electrode pad P3 is exposed from the inorganic insulating film Z3. Meanwhile, since through holes T3′ may be formed at the resin layer J3′ so as to extend over the ends of the electrode pads P3, the positions of the electrode pads P3 may be fixed. Further, when semiconductor chips C3′ are laminated so that the electrode pads P3 overlap each other in the vertical direction, the semiconductor chips may be electrically connected to each other by the embedment of a conductor. Meanwhile, grooves M3′, which communicate with the through holes T3′ from the side surfaces of the resin layer J3′, may be formed. However, at least one of the groove M3′ and the groove M3 may be formed. Furthermore, if having thermoplasticity, at least one of the resin layer J3′ and the resin layer J3 may be used as an adhesive layer at the time of lamination.

### Ninth Embodiment

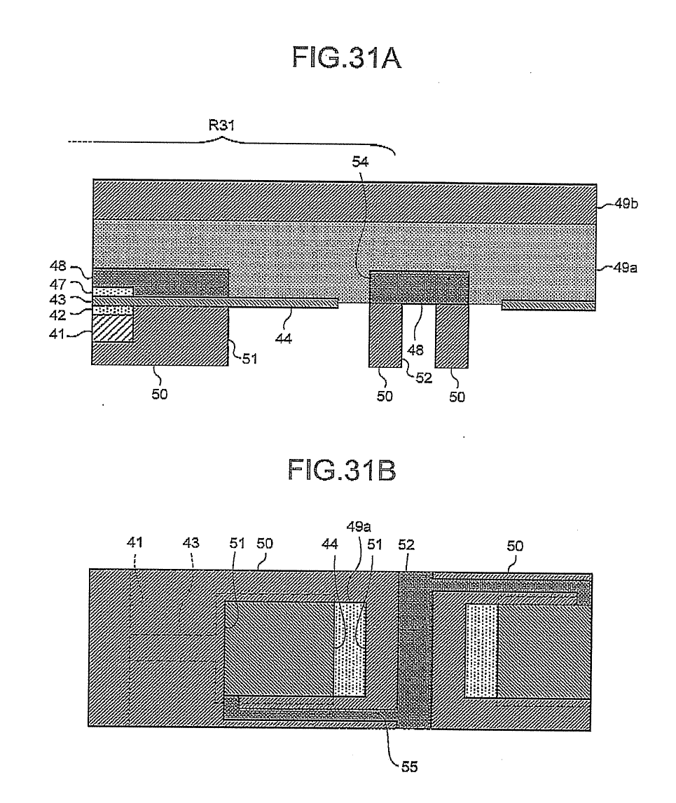

FIG. 31A is a cross-sectional view illustrating a method of manufacturing a semiconductor device according to a ninth embodiment of the invention, and FIG. 31B is a bottom view illustrating the method of manufacturing the semiconductor device according to the ninth embodiment of the invention.

In FIGS. 31A and 31B, when the through hole 51 and the groove 52 of the process illustrated in FIG. 26 are formed at the resin layer 50, a groove 55 for connecting the through hole 51 and the groove 52 of the chip region R31 is collectively formed.

Accordingly, it may be possible to embed a conductor in the through holes 51 and 54 while air existing in the through holes 51 is let out from the grooves 55, and to improve the filling property of the conductor without increasing the number of processes.

### Tenth Embodiment

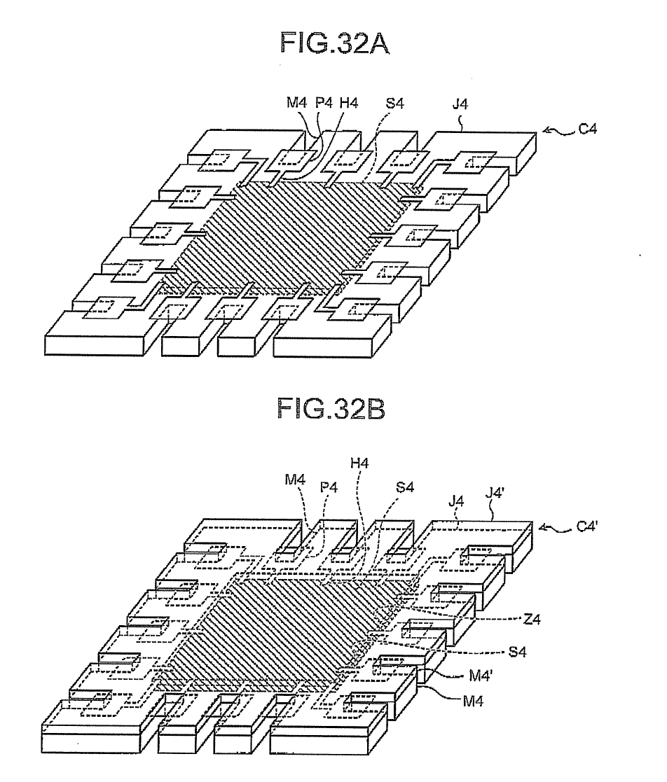

FIG. 32A is a perspective view schematically showing the configuration of a semiconductor device according to a tenth embodiment of the invention, and FIG. 32B is a perspective view showing a modification of the semiconductor device of FIG. 32A.

In FIG. 32A, a semiconductor chip C4 includes a semiconductor substrate S4. Further, a wiring layer is formed on the semiconductor substrate S4, and electrode pads P4 formed integrally with wiring lines H4 are formed at the wiring layer. In this case, the electrode pads P4 are disposed on the same plane as the wiring lines H4 so as to protrude from the sides of the semiconductor substrate S4.

Further, a resin layer J4 is formed on the semiconductor chip C4. In this case, the resin layer J4 is fixed to the semiconductor substrate S4 so as to protrude from the sides of the semiconductor substrate S4. Furthermore, the resin layer J4 is disposed so as to support the electrode pads P4 from below and surround the periphery of the semiconductor substrate S4. Moreover, the surface of the resin layer J4 on which the electrode pads P4 are disposed may be formed to continue to the surface of the semiconductor substrate S4 on which the wiring lines H4 are disposed.

Further, grooves M4, which pass through the resin layer J4 in the vertical direction, are formed on the side surfaces of the resin layer J4. In this case, since the grooves M4 may be disposed so as to extend over the ends of the electrode pads P4, a part of the lower surfaces of the electrode pads P4 are exposed from the resin layer J4. Furthermore, the semiconductor chips C4 are laminated and a conductor is embedded in the grooves M4, so that the semiconductor chips C4, which are laminated in the vertical direction, may be electrically connected to each other.

Accordingly, it may be possible to reduce the stress that is applied to the semiconductor substrate S4 or an inorganic insulating film formed on the semiconductor substrate at the time of connecting semiconductor chips C4. Even when the semiconductor substrate S4 is thinned, it may be possible to prevent cracks from being generated in the semiconductor substrate S4 or the inorganic insulating film.

Meanwhile, in the above-mentioned embodiment, there is no limit on the upper surfaces of the electrode pad P4 and the wiring line H4. However, an insulating film may be laminated on the upper surfaces of the electrode pad and the wiring line. For example, as shown in FIG. 32B, an inorganic insulating film Z4 may be laminated on the semiconductor substrate S4 and a resin layer J4′ may be further laminated on the inorganic insulating film. In this case, a silicon oxide film, a silicon nitride film, a laminated film thereof, or the like may be used as the inorganic insulating film Z4. Polyimide, BCB (benzocyclobutene), PBO (polybenzoxazole), epoxy, phenol, or the like may be used as the resin layer J4′. In this case, openings larger than the electrode pads P4 are formed at the inorganic insulating film Z4, so that the entire upper surface of the electrode pad P4 is exposed from the inorganic insulating film Z4. Meanwhile, grooves M4′, which pass through the resin layer J4′ in the vertical direction, are formed on the side surfaces of the resin layer J4′. In this case, since the grooves M4′ are disposed so as to extend over the ends of the electrode pads P4, a part of the upper surfaces of the electrode pads P4 are exposed from the resin layer J4′. Accordingly, when semiconductor chips C4′ are laminated so that the electrode pads P4 overlap each other in the vertical direction, the semiconductor chips may be electrically connected to each other by the embedment of a conductor. Meanwhile, if having thermoplasticity, at least one of the resin layer J4′ and the resin layer J4 may be used as an adhesive layer at the time of lamination.

### Eleventh Embodiment

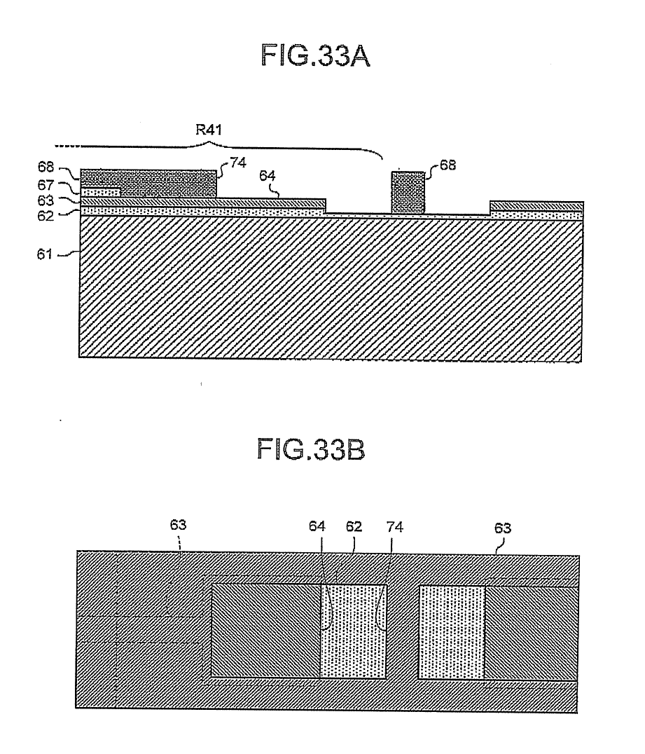

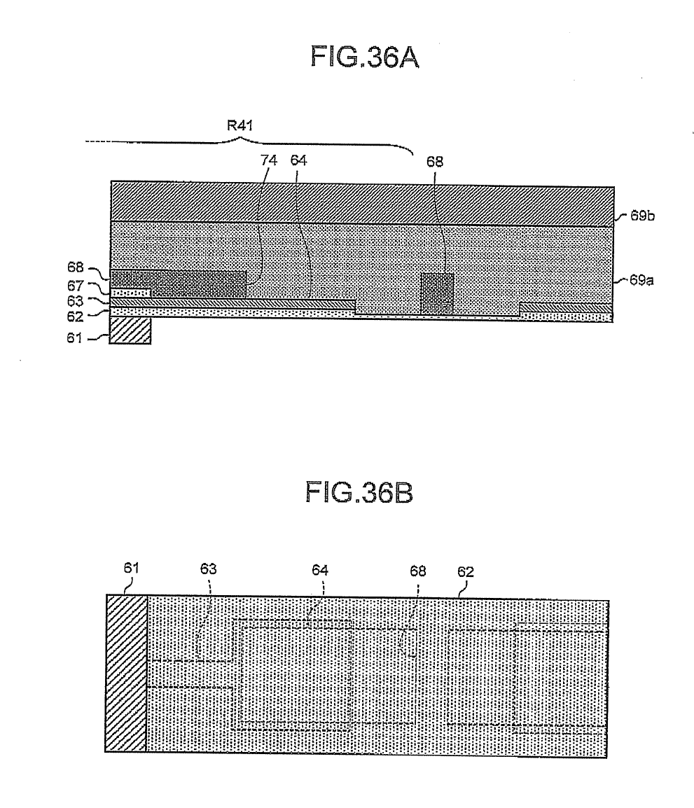

FIGS. 33A, 34, 35, 36A to 40A, and 41 are cross-sectional views illustrating a method of manufacturing a semiconductor device according to an eleventh embodiment of the invention. FIG. 33B is a plan view illustrating the method of manufacturing the semiconductor device according to the eleventh embodiment of the invention. FIGS. 36B to 40B are bottom views illustrating the method of manufacturing the semiconductor device according to the eleventh embodiment of the invention.

In FIGS. 33A and 33B, a resin layer 68 is formed a semiconductor substrate 61 by the same processes as those of FIGS. 3A to 3A and 3B to 6B. Further, through holes 74 through which electrode pads 64 are exposed to the outside are formed at the resin layer 68. Meanwhile, it is preferable that the through hole 74 be disposed so as to extend over the end of the electrode pad 64 and extend over a scribe region between chip regions R41. Furthermore, it is preferable that the resin layer 68 remain in the scribe regions between the chip regions R41.

Meanwhile, an insulating layer 62 is formed on a semiconductor substrate 61, and the electrode pads 64 and wiring lines 63 are formed on the insulating layer 62. In this case, the electrode pads 64 are formed integrally with the wiring lines 63. Further, a passivation film 67 is formed on the wiring lines 63, and the passivation film 67 corresponding to the entire outer peripheral portions of the chip regions R41 is removed, so that the electrode pads 64 are exposed from the passivation film 67. In the embodiment shown in FIGS. 5A and 5B, the opening 15 is formed at the electrode pad 14. However, in the embodiment shown in FIGS. 33A and 33B, an opening is not formed at the electrode pad 64.

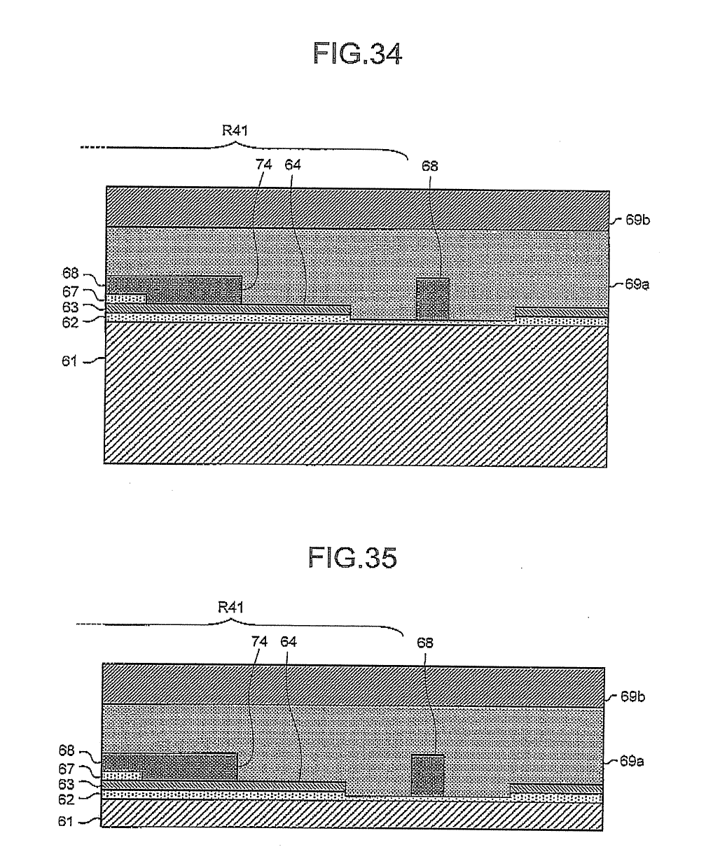

Then, as shown in FIG. 34, a protective sheet 69a and a protective plate 69b, which support the semiconductor substrate 61 during the grinding of the lower surface of the semiconductor substrate 61, are formed on the resin layer 68.

After that, as shown in FIG. 35, the semiconductor substrate 61 is thinned by grinding the lower surface of the semiconductor substrate 61.

Subsequently, as shown in FIGS. 36A and 36B, the semiconductor substrate 61 corresponding to the entire outer peripheral portions of the chip regions R41 is removed by using a photolithography technique and a dry etching technique, and the lower surface of the insulating layer 62 below the electrode pads 64 is exposed from the semiconductor substrate 61. In this case, it is preferable that the semiconductor substrate 61 corresponding to scribe regions between the chip regions R41 also be removed when the semiconductor substrate 61 corresponding to the entire outer peripheral portions of the chip regions R41 is removed.

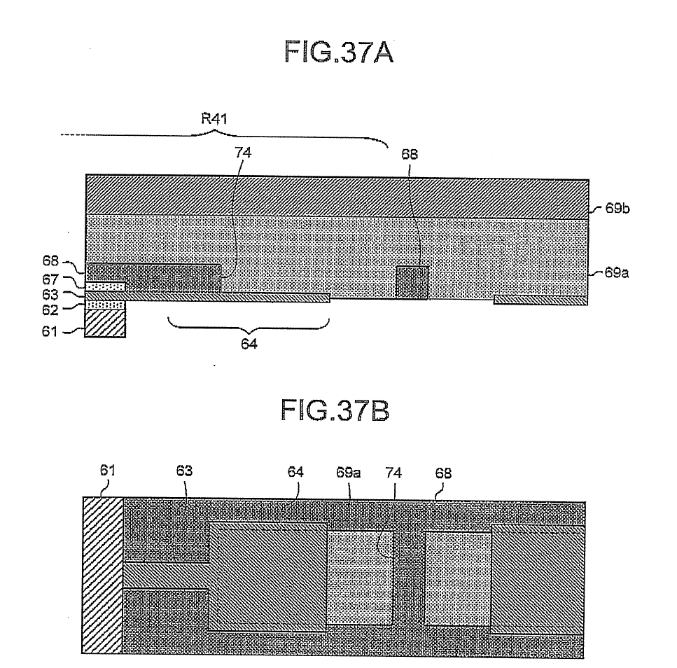

After that, as shown FIGS. 37A and 37B, the insulating layer 62 corresponding to the entire outer peripheral portions of the chip regions R41 is removed by etching the insulating layer 62 while the semiconductor substrate 61 is used as a mask, and the lower surfaces of the electrode pads 64 are exposed from the semiconductor substrate 61. In this case, it is preferable that the insulating layer 62 corresponding to scribe regions between the chip regions R41 also be removed when the insulating layer 62 corresponding to the entire outer peripheral portions of the chip regions R41 is removed.

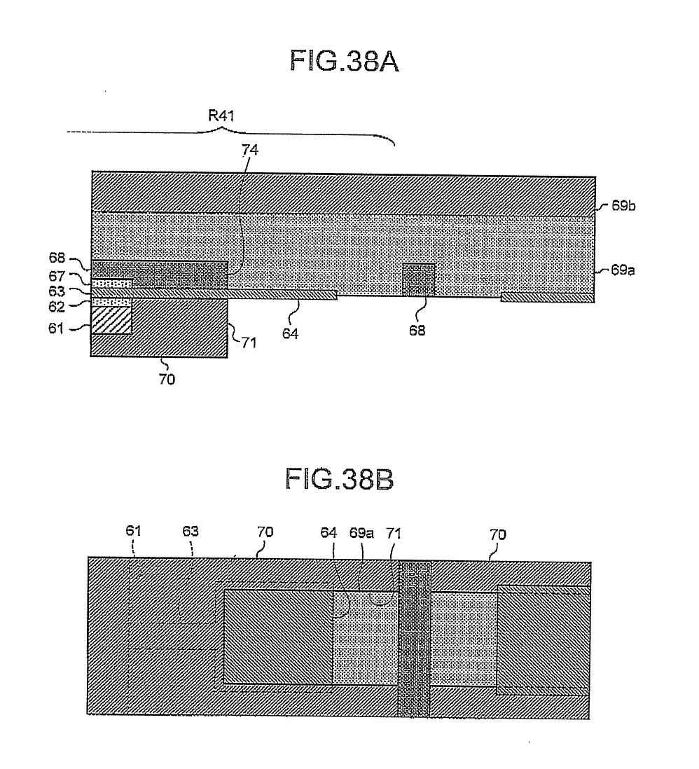

Then, as shown in FIGS. 38A and 38B, a resin layer 70 is formed on the lower surface of the semiconductor substrate 61. Further, the resin layer 70 corresponding to the scribe regions between the chip regions R41 is removed, and grooves 71 through which the lower surfaces of the electrode pads 64 are exposed to the outside are formed on the side surfaces of the resin layer 70. Meanwhile, it is preferable that the groove 71 be disposed so as to extend over the end of the electrode pad 64.

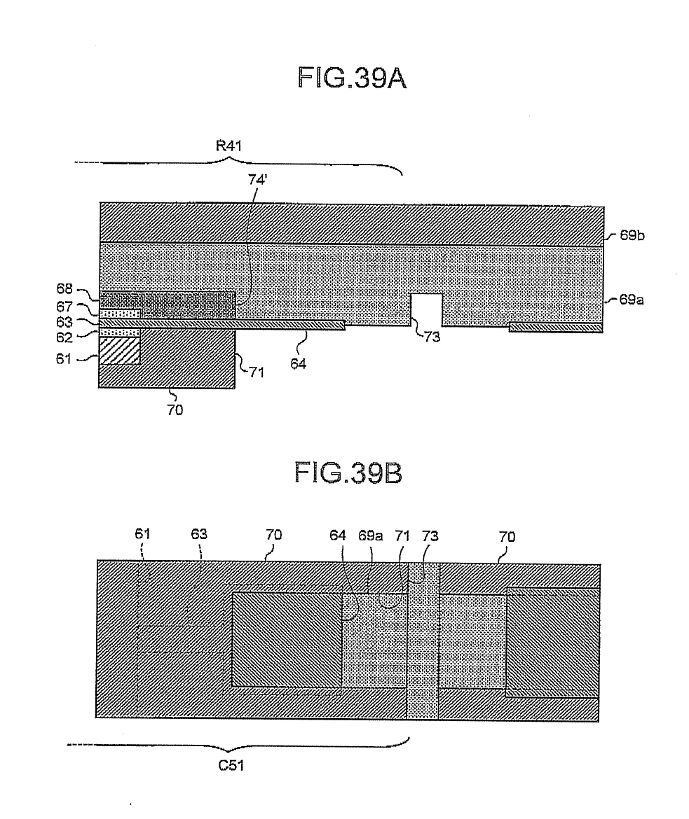

After that, as shown in FIGS. 39A and 39B, the resin layer 68 is removed along the scribe lines between the chip regions R41, grooves 74′ are formed on the side surfaces of the resin layer 68, and a semiconductor chip C51 where the resin layers 68 and 70 are disposed so as to surround the periphery of the semiconductor substrate 61 is cut. In this case, the electrode pads 64 are disposed so as to protrude from the sides of the semiconductor substrate 61, and are supported by the resin layers 68 and 70 that are disposed so as to surround the periphery of the semiconductor substrate 61.

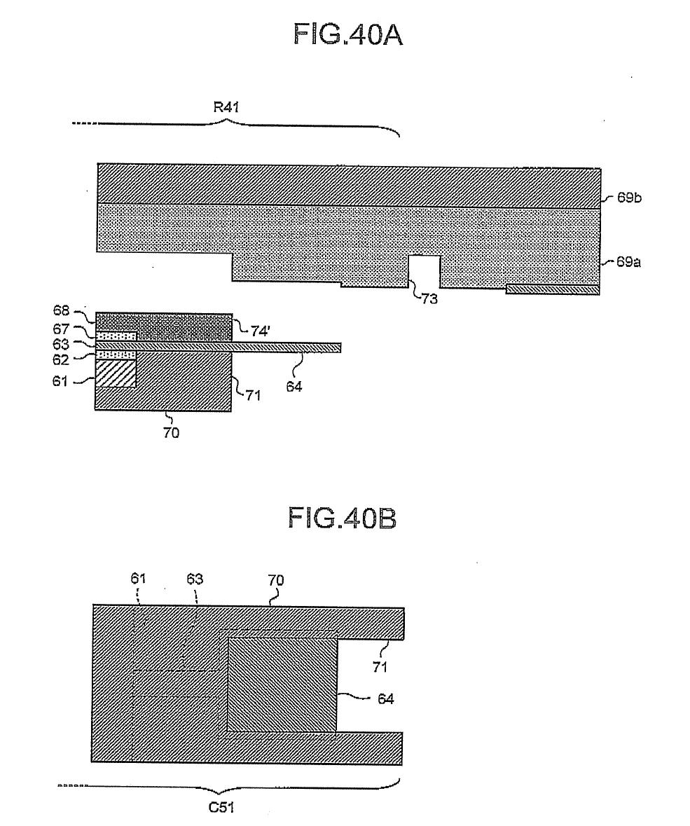

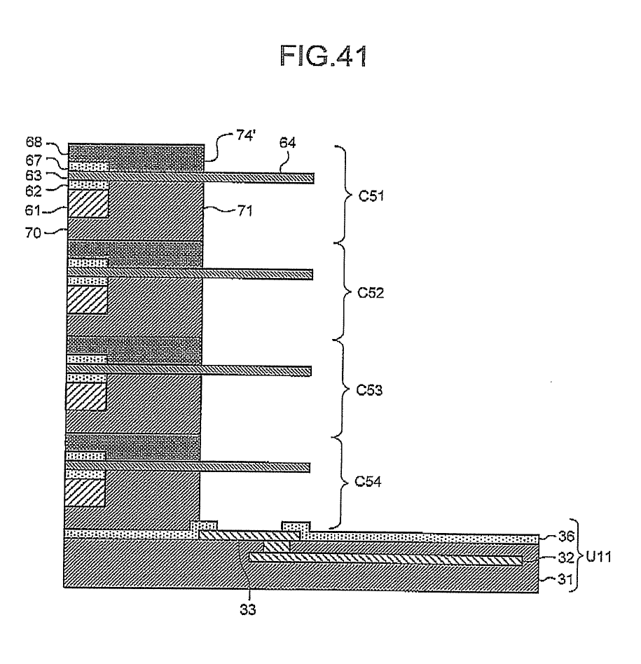

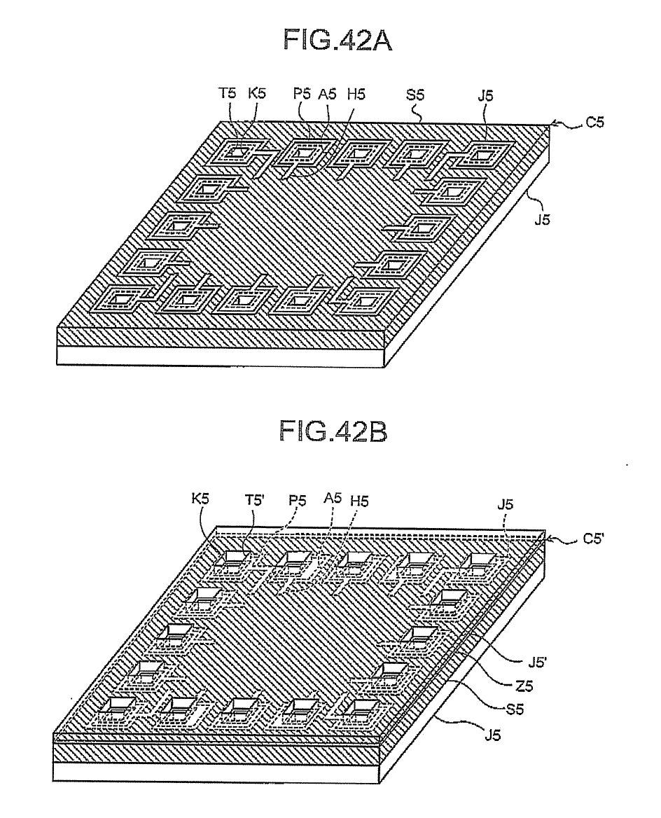

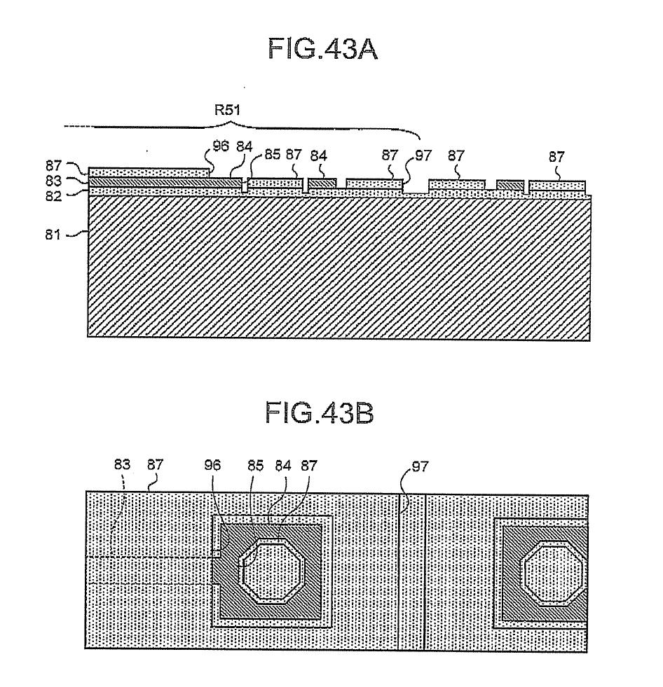

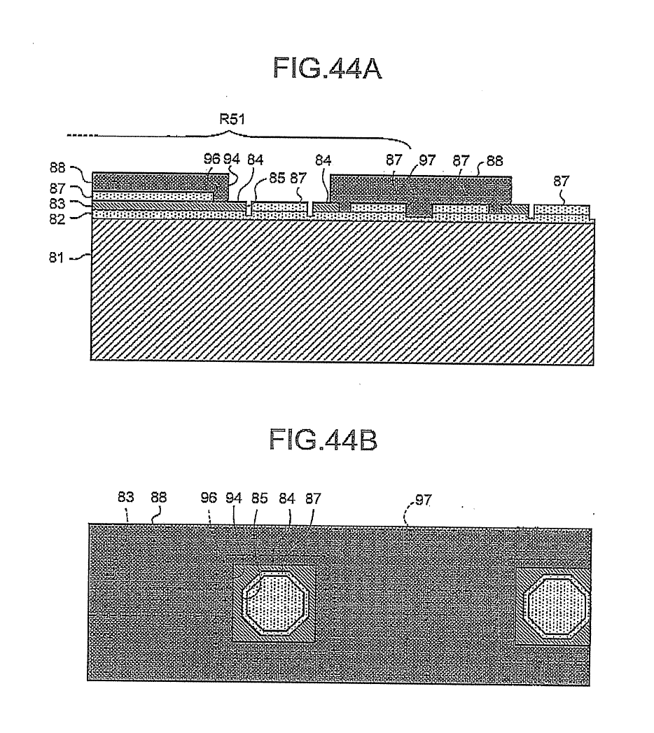

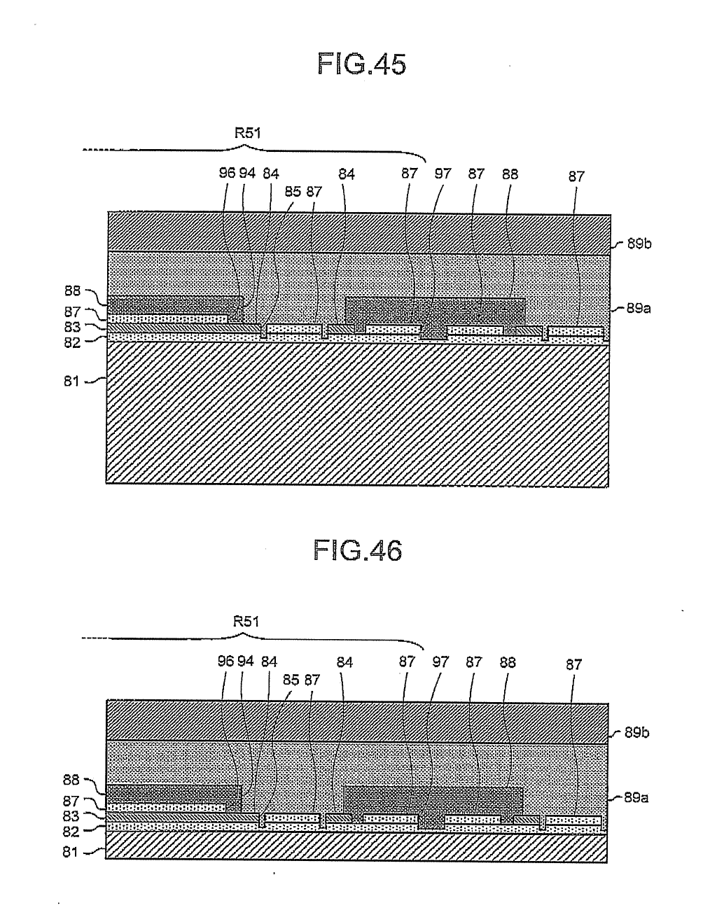

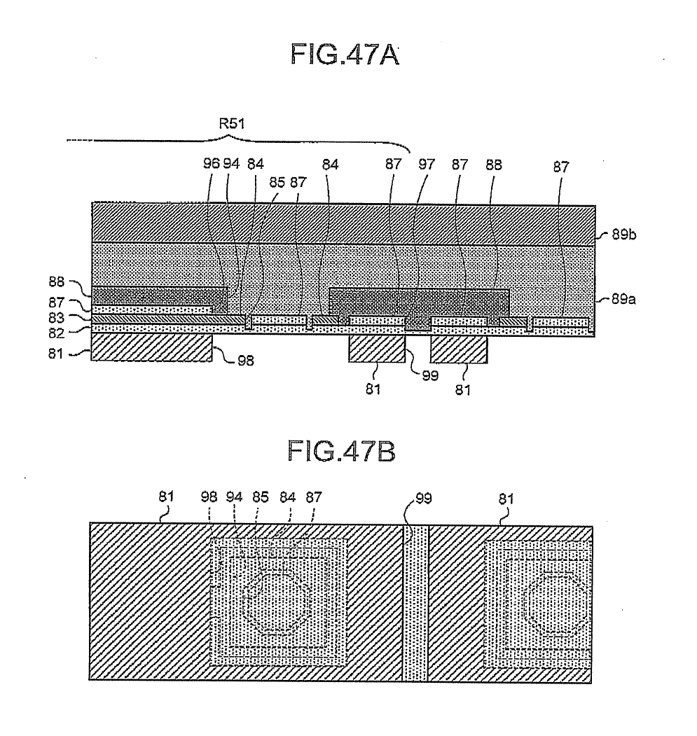

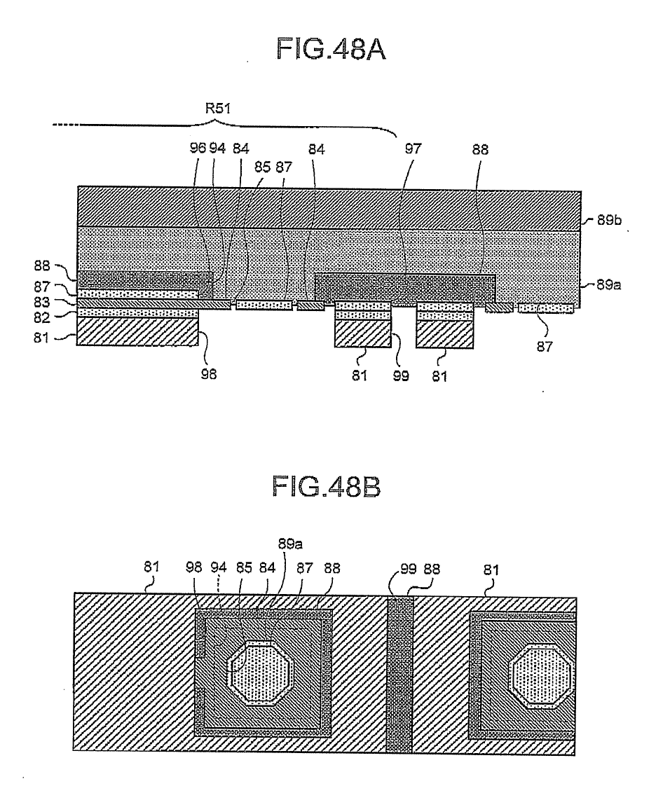

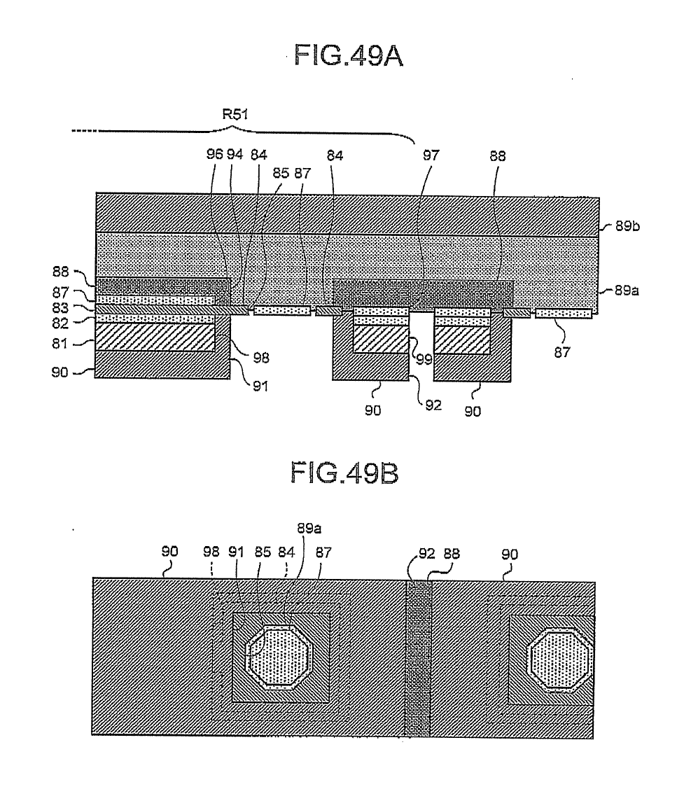

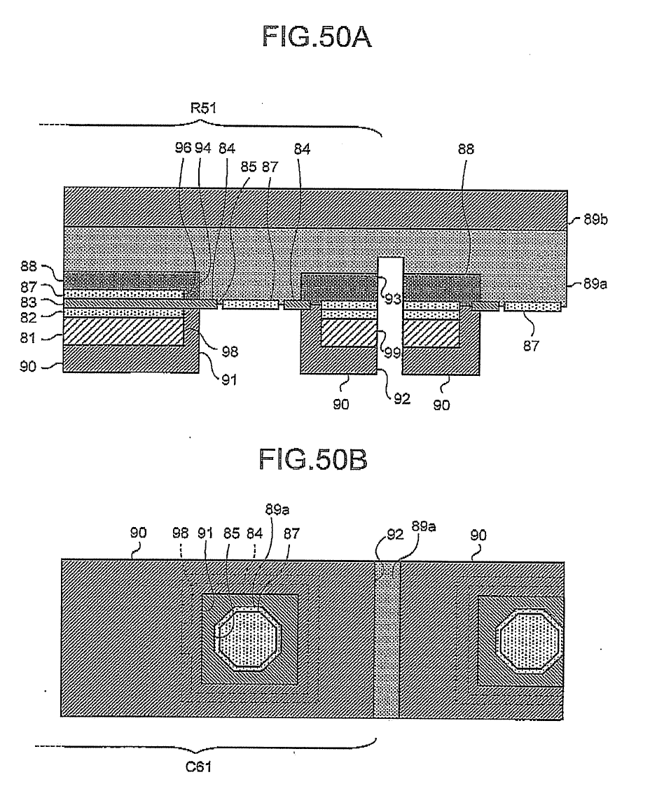

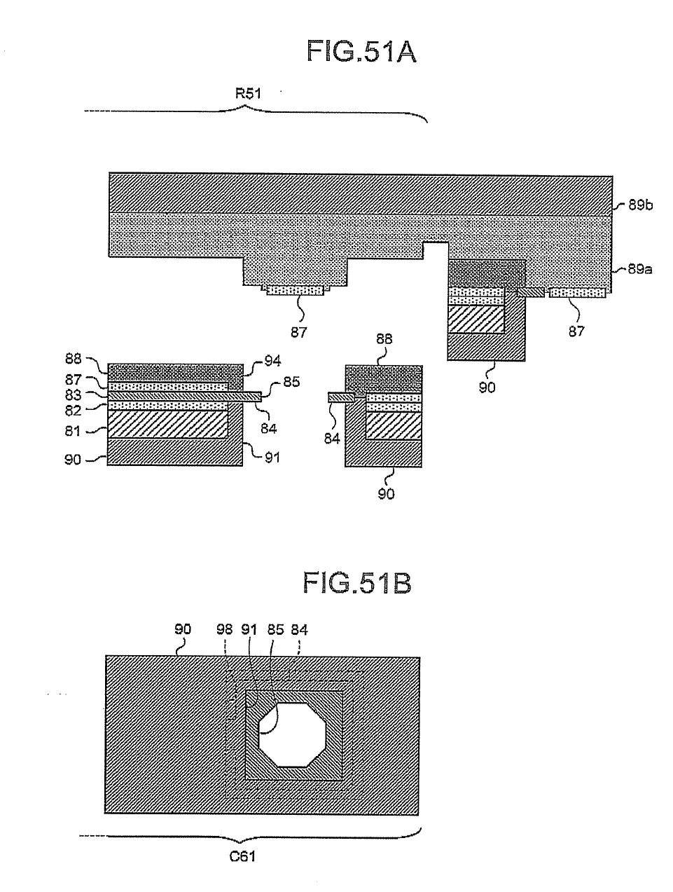

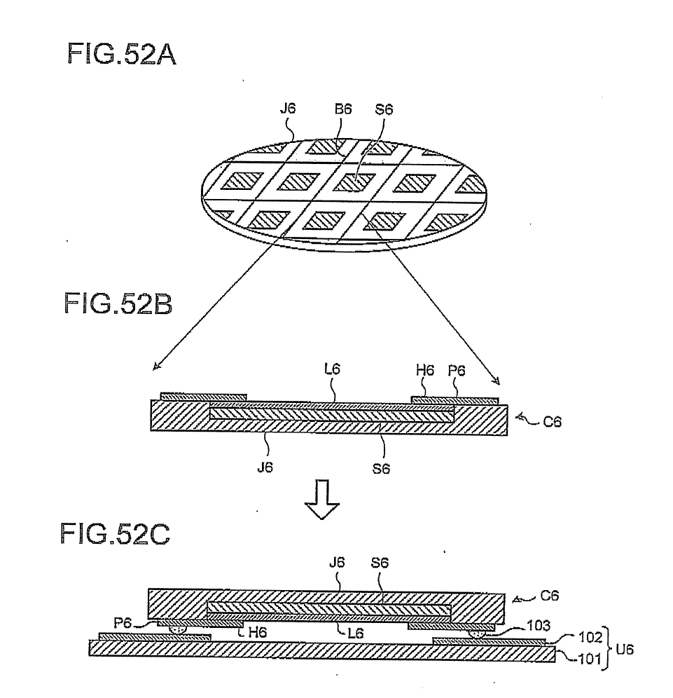

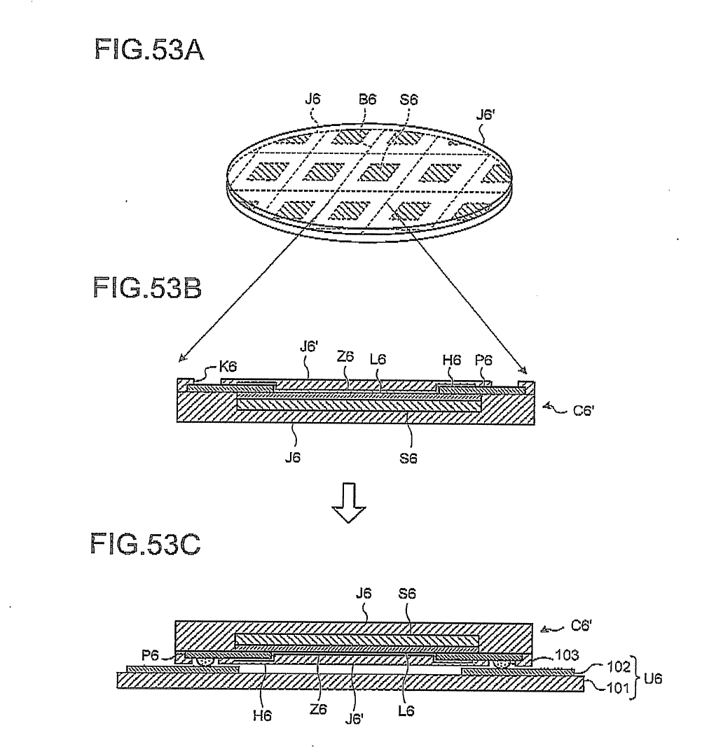

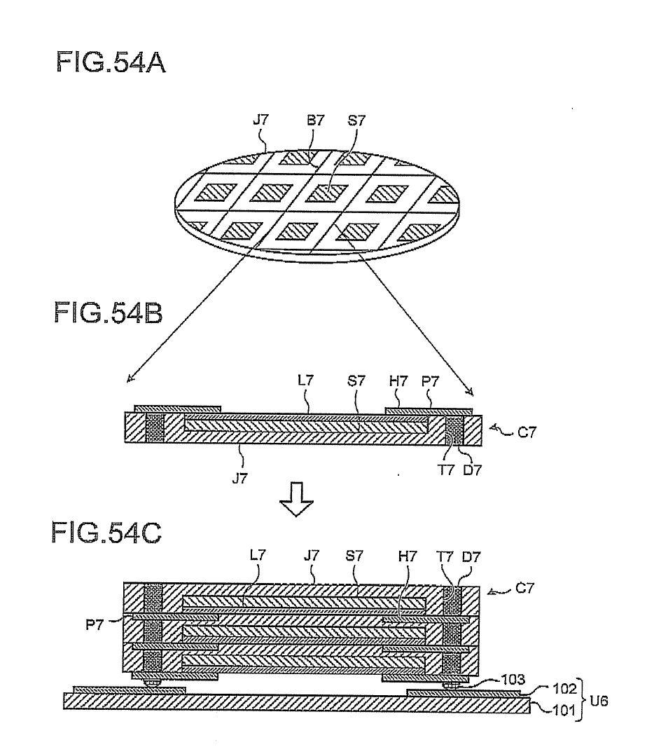

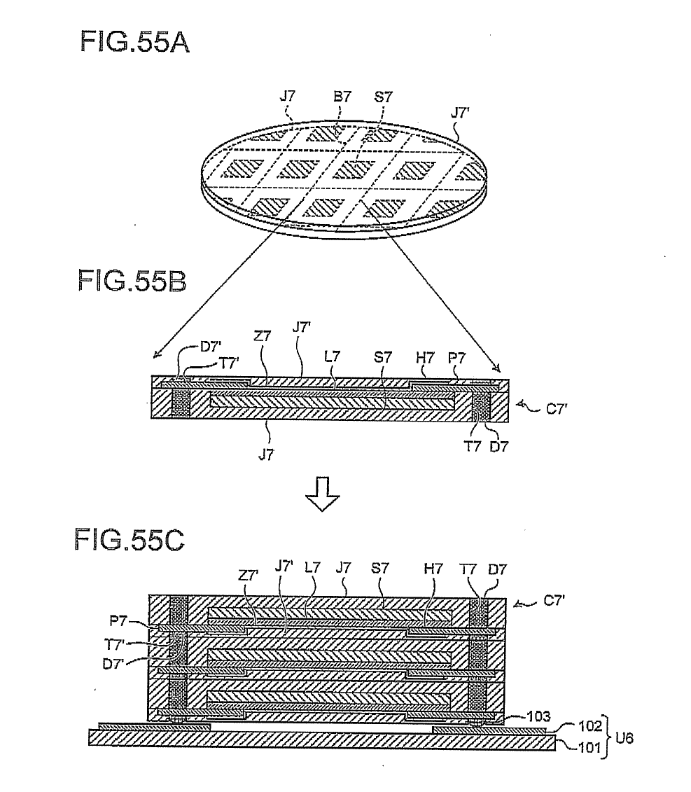

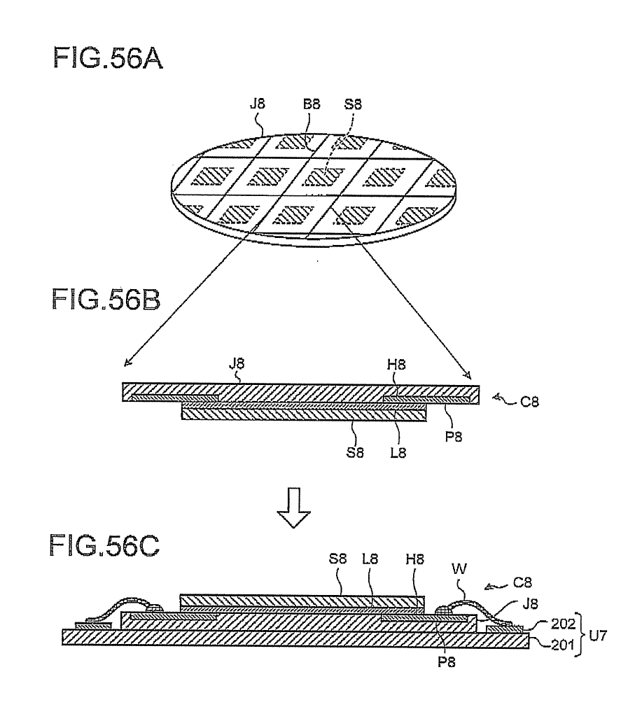

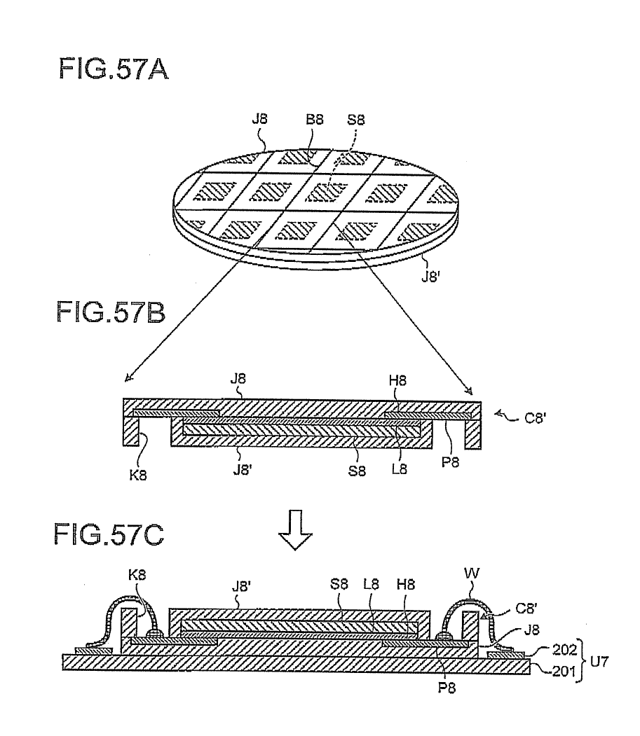

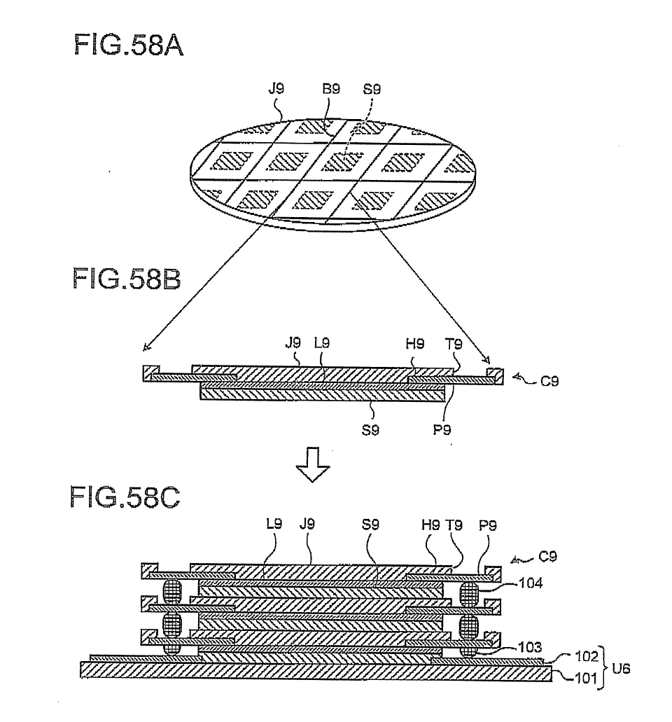

Then, as shown in FIGS. 40A and 40B, the individually cut semiconductor chips C51 are picked up from the protective sheet 69a and the protective plate 69b.

Meanwhile, in this embodiment, the semiconductor chips C51 are cut while being attached to the protective sheet 69a and the protective plate 69b. However, the semiconductor chips C51 may be cut after being detached from the protective sheet 69a and the protective plate 69b.

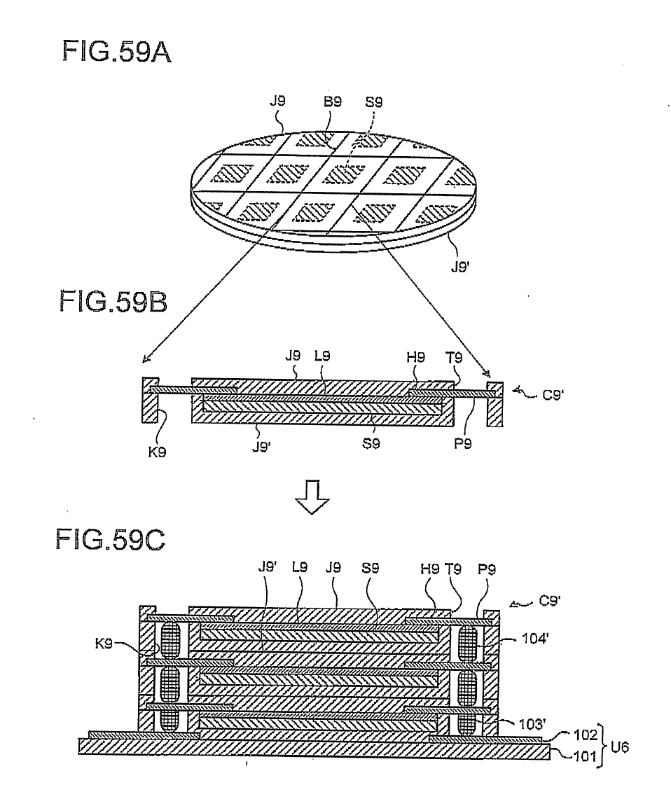

Subsequently, as shown in FIG. 41, while the resin layer 70 is heated, semiconductor chips C51 to C54 are sequentially laminated on a mounting substrate U11 so that the electrode pads 64 overlap each other in the vertical direction. Further, a conductor is embedded in the grooves 71 and 74′, so that the upper and lower electrode pads 64 are electrically connected to each other and the semiconductor chips C51 to C54, which are laminated in the vertical direction, are electrically connected to each other. Meanwhile, each of the semiconductor chips C52 to C54 may be formed to have the same structure as the semiconductor chip C51.

Accordingly, it may be possible to reduce the stress, which is applied to the semiconductor substrate 61, the insulating layer 62, or the passivation film 67 at the time of connecting the upper and lower electrode pads 64. For this reason, even when the semiconductor substrate 61 is thinned, it may be possible to prevent cracks from being generated in the semiconductor substrate 61, the insulating layer 62, or the passivation film 67.

### Twelfth Embodiment

FIG. 42A is a perspective view schematically showing the configuration of a semiconductor device according to a twelfth embodiment of the invention, and FIG. 42B is a perspective view showing a modification of the semiconductor device of FIG. 42A.

In FIG. 42A, a semiconductor chip C5 includes a semiconductor substrate S5. Further, a wiring layer is formed on the semiconductor substrate S5, and electrode pads P5 formed integrally with wiring lines H5 are formed at the wiring layer. Through holes A5 are formed at the semiconductor substrate S5. In this case, the through holes AS are formed so that the semiconductor substrate S5 does not exist below the electrode pads P5. The inner peripheral portion of the through hole A5 may be disposed outside the outer peripheral portion of the electrode pad P5.

Further, a resin layer J5 is formed on the semiconductor chip C5. In this case, the resin layer J5 is fixed to the semiconductor substrate S5 so as to be embedded in the through holes A5. Furthermore, the resin layer J5 is disposed so as to support the electrode pads P5 from below.

Further, an opening K5 is formed at each of the electrode pads P5, and through holes T5, which pass through the resin layer J5 in a vertical direction, are formed at the resin layer J5. In this case, the through holes T5 may be disposed so as to pass through the electrode pads P5 through the openings K5 in the vertical direction, respectively. Furthermore, the semiconductor chips C5 are laminated and a conductor is embedded in the through holes T5, so that the semiconductor chips C5, which are laminated in the vertical direction, may be electrically connected to each other.

Accordingly, the electrode pads P5 may be disposed not to interfere with the semiconductor substrate S5, and it may be possible to reduce the stress that is applied to the semiconductor substrate S5 or an inorganic insulating film formed on the semiconductor substrate at the time of connecting semiconductor chips C5. For this reason, even when the semiconductor substrate S5 is thinned, it may be possible to prevent cracks from being generated in the semiconductor substrate S5 or the inorganic insulating film.

Meanwhile, in the above-mentioned embodiment, there is no limit on the upper surfaces of the electrode pad P5 and the wiring line H5. However, an insulating film may be laminated on the upper surfaces of the electrode pad and the wiring line. For example, as shown in FIG. 42B, an inorganic insulating film Z5 may be laminated on the semiconductor substrate S5 and a resin layer J5′ may be further laminated on the inorganic insulating film. In this case, a silicon oxide film, a silicon nitride film, a laminated film thereof, or the like may be used as the inorganic insulating film Z5. Polyimide, BCB (benzocyclobutene), PBO (polybenzoxazole), epoxy, phenol, or the like may be used as the resin layer J5′. In this case, openings larger than the electrode pads P5 are formed at the inorganic insulating film Z5, so that the entire upper surface of the electrode pad P5 is exposed from the inorganic insulatinc film Z5. Meanwhile, if through holes T5′, which are smaller than the electrode pads P5 and larger than the openings K5 of the electrode pads P5, are formed at the resin layer J5′, the outer peripheries of the electrode pads P5 are fixed, a part of the upper surfaces of the electrode pads P5 and the openings K5 are exposed, and the positions of the electrode pads P5 may be fixed. Further, when semiconductor chins C5′ are laminated so that the electrode pads P5 overlap each other in the vertical direction, the semiconductor chips may be electrically connected to each other by the embedment of a conductor. Meanwhile, if having thermoplasticity, at least one of the resin layer J5′ and the resin layer J5 may be used as an adhesive layer at the time of lamination.

### Thirteenth Embodiment

FIGS. 43A, 44A, 45, 46, and 47A to 51A are cross-sectional views illustrating a method of manufacturing a semiconductor device according to a thirteenth embodiment of the invention. FIGS. 43B to 44B are plan views illustrating the method of manufacturing the semiconductor device according to the thirteenth embodiment of the invention. FIGS. 47B to 51B are bottom views illustrating the method of manufacturing the semiconductor device according to the thirteenth embodiment of the invention.

In FIGS. 43A and 43B, an insulating layer 82 is formed on a semiconductor substrate 81, and wiring lines 83 formed integrally with electrode pads 84 are formed on the insulating layer 82. In this case, an opening 85 is formed at each of the electrode pads 84. Further, a passivation film 87 is formed cn the wiring lines 83 and the electrode pads 84 by a CVD method or the like. Further, the passivation film 87 around the electrode pads 84 is removed by using a photolithography technique and a dry etching technique, and portions around the electrode pads 84 are exposed from the passivation film 87. In this case, it is preferable that the passivation film 87 corresponding to scribe regions between chip regions R51 also be removed when the passivation film 87 around the electrode pads 84 is removed. Further, it is preferable that the passivation film 87 remains inside the openings 85 of the electrode pads 84.

After that, as shown in FIGS. 44A and 44B, a resin layer 88 is formed on the semiconductor substrate 81. Further, through holes 94 through which the electrode pads 84 are exposed to the outside are formed at the resin layer 88. Meanwhile, it is preferable that the through hole 94 be disposed inside the outer peripheral portion of the electrode pad 84 and outside the opening 85. Furthermore, it is preferable that the resin layer 88 remain at the outer peripheral portions of the chip regions R51.

Then, as shown in FIG. 45, a protective sheet 89a and a protective plate 89b, which support the semiconductor substrate 81 during the grinding of the lower surface of the semiconductor substrate 81, are formed on the resin layer 88.

After that, as shown in FIG. 46, the semiconductor substrate 81 is thinned by grinding the lower surface of the semiconductor substrate 81.

Subsequently, as shown in FIGS. 47A and 47B, by a photolithography technique and a dry etching technique, through holes 98 through which the lower surface of the insulating layer 82 below the electrode pads 84 are exposed to the outside are formed at the semiconductor substrate 81 and grooves 99 through which the scribe regions between the chip regions R51 are exposed to the outside are formed at the semiconductor substrate 81. Meanwhile, it is preferable that the inner peripheral portion of the through hole 98 be disposed outside the outer peripheral portion of the electrode pad 84.

After that, as shown FIGS. 48A and 48B, the insulating layer 82 below the electrode pads 84 is removed by etching the insulating layer 82 while the semiconductor substrate 81 is used as a mask, and the lower surfaces of the electrode pads 84 are exposed from the semiconductor substrate 81. In this case, it is preferable that the insulating layer S2 corresponding to scribe regions between the chip regions R51 also be removed when the insulating layer 82 below the electrode pads 84 is removed.

In this case, if the passivation film 87 remains inside the openings 85 of the electrode pads 84, it may be possible to protect the protective sheet 89a by the passivation film 87 and to suppress the damage of the protective sheet 89a when the insulating layer 82 is removed by etching.

Then, as shown in FIGS. 49A and 49B, a resin layer 90 is formed on the lower surface of the semiconductor substrate 81. Further, through holes 91 through which the lower surfaces of the electrode pads 84 are exposed to the outside are formed at the resin layer 90, and grooves 92 through which the scribe regions between the chip regions R51 are exposed to the outside are formed at the resin layer 90. Meanwhile, it is preferable that the inner peripheral portion of the through hole 91 be disposed inside the outer peripheral portion of the electrode pad 84 and outside the outer peripheral portion of the opening 85.

After that, as shown in FIGS. 50A and 50B, the resin layer 88 is cut by forming a groove 93 at the resin layer 88 along the scribe lines between the chip regions R51, and a semiconductor chip C61 where the resin layer 90 is disposed not to interfere with portions below the electrode pads 84 is cut.

Then, as shown in FIGS. 51A and 51B, the individually cut semiconductor chips C61 are picked up from the protective sheet 89a and the protective plate 89b. Further, while the resin layer 90 is heated, semiconductor chips C61 are laminated so that the electrode pads 84 overlap each other in the vertical direction. Furthermore, a conductor is embedded in the through holes 91 and 94, so that the upper and lower electrode pads 84 are electrically connected to each other and the semiconductor chips C61, which are laminated in the vertical direction, are electrically connected to each other.

Accordingly, it may be possible to reduce the stress, which is applied to the semiconductor substrate 81, the insulating layer 82, or the passivation film 87 at the time of connecting the upper and lower electrode pads 84. For this reason, even when the semiconductor substrate 81 is thinned, it may be possible to prevent cracks from being generated in the semiconductor substrate 81, the insulating layer 82, or the passivation film 87.

Meanwhile, in this embodiment, the semiconductor chips C61 are cut while being attached to the protective sheet 89a and the protective plate 89b. However, the semiconductor chips C61 may be cut after being detached from the protective sheet 89a and the protective plate 89b.

Meanwhile, the method, which makes the passivation film 87 remain inside the opening 85 of the electrode pad 84 in order to protect the protective sheet 89a when the insulating layer 82 is removed by etching, has been described in the above-mentioned thirteenth embodiment. However, the passivation film 87 may not remain inside the opening 85 of the electrode pad 84.

Further, even in the above-mentioned second, seventh, ninth, and eleventh embodiments, the passivation film may remain at the exposed portion of the protective sheet in order to protect the protective sheet when the insulating layer below the electrode pads is removed by etching.

### Fourteenth Embodiment

FIGS. 52A, 52B, and 52C are views illustrating a method of manufacturing a semiconductor device according to a fourteenth embodiment of the invention, and FIGS. 53A, 53B, and 53C are views showing a modification of the method of manufacturing the semiconductor device of FIGS. 52A, 52B, and 52C.

In FIGS. 52A, 52B, and 52C, a semiconductor substrate S6 is separated into each chip region. Further, a wiring layer L6 is formed on each semiconductor substrate S6. Wiring lines H6 that are formed integrally with electrode pads P6, and an interlayer insulating film that insulates the wiring lines H6 from the semiconductor substrate S6 are formed on the wiring layer L6. In this case, the electrode pads P6 are disposed so as to protrude from the sides of the semiconductor substrate S6. Meanwhile, a field-effect transistor may be formed on each semiconductor substrate S6. Alternatively, a flash memory, a DRAM, a microcomputer, a logic circuit, an image sensor, or the like may be formed on each semiconductor substrate.

Further, a resin layer J6 is formed around these separated semiconductor substrates S6, and is fixed to the semiconductor substrates S6. Accordingly, the electrode pads P6 protruding from the sides of the semiconductor substrate S6 are supported by the resin layer, and the semiconductor substrates S6 separated into the respective chip regions are integrally supported by the resin layer.

Furthermore, it may be possible to cut a semiconductor chip C6 where the resin layer J6 is disposed so as to surround the periphery of the semiconductor substrate S6, by cutting the resin layer J6 along scribe lines B6. In the semiconductor chip C6, the electrode pads P6 are disposed so as to protrude from the sides of the semiconductor substrate S6 and are supported on the resin layer J6 that is disposed so as to surround the periphery of the semiconductor substrate S6.

Meanwhile, a mounting substrate U6 includes an insulating substrate 101, and land electrodes 102 are formed on the insulating substrate 101. Further, it may be possible to mount the semiconductor chip C6 on the mounting substrate U6 by bonding the electrode pads P6 to the land electrodes 102 through protruding electrodes 103.

Accordingly, it may be possible to reduce the stress, which is applied to the semiconductor substrate S6 or an inorganic insulating film at the time of bonding the electrode pads P6 to the land electrodes 102. Even when the semiconductor substrate S6 is thinned, it may be possible to prevent cracks from being generated in the semiconductor substrate S6 or the inorganic insulating film.

Meanwhile, for example, an Au bump, a Ni bump or a Cu bump coated with a solder material or the like, a solder ball, or the like may be used as the protruding electrode 103. Further, when the semiconductor chip C6 is mounted on the mounting substrate U6, metal bonding, such as solder bonding or alloy bonding, may be used or pressure-welding bonding, such as ACF (Anisotropic Conductive Film) bonding, NCF (Nonconductive Film) bonding, ACP (Anisotropic Conductive Paste) bonding, or NCP (Nonconductive Paste) bonding, may be used.

Meanwhile, an insulating film may be laminated on the upper surface of the semiconductor chip C6. For example, as shown in FIGS. 53A, 53B, and 53C, an inorganic insulating film Z6 is laminated on the wiring lines H6, and a resin layer J6′ may be further laminated on the inorganic insulating film. In this case, a silicon oxide film, a silicon nitride film, a laminated film thereof, or the like may be used as the inorganic insulating film Z6. Polyimide, BCB (benzocyclobutene), PBO (polybenzoxazole), epoxy, phenol, or the like may be used as the resin layer J6′. In this case, openings larger than the electrode pads P6 are formed at the inorganic insulating film Z6, so that the entire upper surface of the electrode pad P6 is exposed from the inorganic insulating film Z6. Meanwhile, the electrode pads P6 are bonded to the land electrodes 102 through the protruding electrodes 103 by forming through holes K6, which are smaller than the electrode pads P6, at the resin layer J6′, fixing the outer peripheries of the electrode pads P6, and exposing a part of the upper surfaces of the electrode pads P6. Accordingly, it may be possible to mount the semiconductor chip C6′ on the mounting substrate U6.

### Fifteenth Embodiment

FIGS. 54A, 54B, and 54C are views illustrating a method of manufacturing a semiconductor device according to a fifteenth embodiment of the invention, and FIGS. 55A, 55B, and 55C are views showing a modification of the method of manufacturing the semiconductor device of FIGS. 54A, 54B, and 54C.

In FIGS. 54A, 54B, and 54C, a semiconductor substrate S7 is separated into each chip region. Further, a wiring layer L7 is formed on each semiconductor substrate S7. Wiring lines H7 that are formed integrally with electrode pads P7, and an interlayer insulating film that insulates the wiring lines H7 from the semiconductor substrate S7 are formed on the wiring layer L7. In this case, the electrode pads P7 are disposed so as to protrude from the sides of the semiconductor substrate S7.

Further, a resin layer J7 is formed around these separated semiconductor substrates S7, and is fixed to the semiconductor substrates S7. Accordingly, the electrode pads P7 protruding from the sides of the semiconductor substrate S7 are supported by the resin layer, and the semiconductor substrates S7 separated into the respective chip regions are integrally supported by the resin layer.

Furthermore, it may be possible to cut a semiconductor chip C7 where the resin layer J7 is disposed so as to surround the periphery of the semiconductor substrate S7, by cutting the resin layer J7 along scribe lines B7. In the semiconductor chip C7, the electrode pads P7 are disposed so as to protrude from the sides of the semiconductor substrate S7 and are supported on the resin layer J7 that is disposed so as to surround the periphery of the semiconductor substrate S7.

Further, through holes T7, which pass through the resin layer J7 in the vertical direction so that the lower surfaces of the electrode pads P7 are exposed to the outside, are formed at the resin layer J7. Furthermore, a conductor D7 is embedded in the through hole T7. Meanwhile, the formation of the through hole T7 and the embedment of the conductor D7 may be performed while the separated semiconductor substrates S7 are integrally supported by the resin layer J7. Further, for example, an ink jet method, which discharges a conductive paste from a nozzle in a dot shape, may be used for the embedment of the conductor D7.

Furthermore, it may be possible to cut a semiconductor chip C7 where the resin layer J7 is disposed so as to surround the periphery of the semiconductor substrate S7, by cutting the resin layer J7 along scribe lines B7. In the semiconductor chip C7, the electrode pads P7 are disposed so as to protrude from the sides of the semiconductor substrate S7 and are supported on the resin layer J7 that is disposed so as to surround the periphery of the semiconductor substrate S7. Moreover, it may be possible to electrically connect the semiconductor chips C7, which are laminated in the vertical direction, by laminating the semiconductor chips C7 so that the electrode pads P7 overlap each other in the vertical direction, and electrically connecting the upper and lower electrode pads P7 through the conductor D7. Further, it may be possible to mount the laminated semiconductor chips C7 on the mounting substrate U6 by bonding the electrode pads P7 of the lowermost semiconductor chip C7 to the land electrodes 102 through the protruding electrodes 103.

Accordingly, it may be possible to electrically connect the semiconductor chips C7, which are laminated in the vertical direction, without forming openings at the electrode pads P7, to reduce the stress that is applied to the semiconductor substrate S7 or an inorganic insulating film at the time of connecting the semiconductor chips C7, and to prevent cracks from being generated in the semiconductor substrate S7 or the inorganic insulating film.

Meanwhile, an insulating film may be laminated on the upper surface of the semiconductor chip C1. For example, as shown in FIGS. 55A, 55B, and 55C, an inorganic insulating film Z7 is laminated on the wiring lines H7, and a resin layer J7′ may be further laminated on the inorganic insulating film. In this case, a silicon oxide film, a silicon nitride film, a laminated film thereof, or the like may be used as the inorganic insulating film Z7. Polyimide, BCB (benzocyclobutene), PBO (polybenzoxazole), epoxy, phenol, or the like may be used as the resin layer J7′. In this case, openings larger than the electrode pads P7 are formed at the inorganic insulating film Z7, so that the entire upper surface of the electrode pad P7 is exposed from the inorganic insulating film Z7. Meanwhile, the electrode pads P7 are bonded to the land electrodes 102 through the protruding electrodes 103 by forming through hole T7′, which are smaller than the electrode pads P7, at the resin layer J7′, fixing the outer peripheries of the electrode pads P7, and exposing a part of the upper surfaces of the electrode pads P7. Accordingly, it may be possible to mount the semiconductor chips C7′ on the mounting substrate U6.

### Sixteenth Embodiment

FIGS. 56A, 56B, and 56C are views illustrating a method of manufacturing a semiconductor device according to a sixteenth embodiment of the invention, and FIGS. 57A, 57B, and 57C are views showing a modification of the method of manufacturing the semiconductor device of FIGS. 56A, 56B, and 56C.

In FIGS. 56A, 56B, and 56C, a semiconductor substrate S8 is separated into each chip region. Further, a wiring layer L8 is formed on each semiconductor substrate S8. Wiring lines H8 that are formed integrally with electrode pads P8, and an interlayer insulating film that insulates the wiring lines H8 from the semiconductor substrate S8 are formed on the wiring layer L8. In this case, the electrode pads P8 are disposed so as to protrude from the sides of the semiconductor substrate S8.

Further, a resin layer J8 is formed on these separated semiconductor substrates S8, and is fixed to the semiconductor substrates S8. Accordingly, the electrode pads P8 protruding from the sides of the semiconductor substrate S8 are supported by the resin layer, and the semiconductor substrates S8 separated into the respective chip regions are integrally supported by the resin layer.

Furthermore, it may be possible to cut a semiconductor chip C8 where the resin layer J8 is disposed on the semiconductor substrate S8, by cutting the resin layer J8 along scribe lines B8. In the semiconductor chip C8, the resin layer J8 is disposed so as to protrude from the sides of the semiconductor substrate S8. Moreover, the electrode pads P8 are disposed so as to protrude from the sides of the semiconductor substrate S8 and are supported below the resin layer J8 that is disposed on the semiconductor substrate S8.

Meanwhile, a mounting substrate U7 is provided with an insulating substrate 201, and land electrodes 202 are formed on the insulating substrate 201. Further, it may be possible to mount the semiconductor chip C8 on the mounting substrate U7 by attaching the resin layer J8 onto the mounting substrate U7 and connecting the electrode pads P8 to the land electrodes 202 through bonding wires W.

In this case, if the resin layer J8 has thermoplasticity, the resin layer J8 may be used as an adhesive between the semiconductor chip C8 and the mounting substrate U7.

Accordingly, it may be possible to reduce the stress that is applied to the semiconductor substrate S8 or an inorganic insulating film at the time of connecting the bonding wire W to the electrode pad P8, to prevent cracks from being generated in the semiconductor substrate S8 or the inorganic insulating film, and to reduce the number of processes without forming through holes at the resin layer J8.

Meanwhile, an inorganic insulating film may be laminated below the resin layer J8. In this case, it is preferable that the entire upper surface of the electrode pad P8 be exposed from the inorganic insulating film by forming openings larger than the electrode pads P8 at the inorganic insulating film.

Further, as shown in FIGS. 57A, 57B, and 57C, a resin film J8′ may be laminated on the lower surface of the semiconductor substrate S8. Through holes K8 smaller than the electrode pads P8 are formed at the resin layer J8′, the outer peripheries of the electrode pads PS are fixed, and a part of the lower surfaces of the electrode pads P8 are exposed to the outside. Furthermore, it may be possible to mount the semiconductor chip C8 on the mounting substrate U7 by attaching the resin layer J8 onto the mounting substrate U7 and connecting the electrode pads P8 to the land electrodes 202 through bonding wires W.

In addition, through holes smaller than the electrode pads P8 may be formed at the resin layer J8 without forming the through holes K8, the outer peripheries of the electrode pads P8 may be fixed, and a part of the upper surfaces of the electrode pads P8 may be exposed to the outside. Further, it may be possible to mount a semiconductor chip C8′ on the mounting substrate U7 by attaching a resin layer J8′, which is formed on the lower surface of the semiconductor substrate, to the mounting substrate U7 and connecting the electrode pads P8 to the land electrodes 202 through bonding wires W. In this case, if the resin layer J8′ formed on the lower surface of the semiconductor substrate has thermoplasticity, the resin layer J8′ may be used as an adhesive between the semiconductor chip C8′ and the mounting substrate U7.

### Seventeenth Embodiment

FIGS. 58A, 58B, and 58C are views illustrating a method of manufacturing a semiconductor device according to a seventeenth embodiment of the invention, and FIGS. 59A, 59B, and 59C are views showing a modification of the method of manufacturing the semiconductor device of FIGS. 58A, 58B, and 58C.

In FIGS. 58A, 58B, and 58C, a semiconductor substrate S9 is separated into each chip region. Further, a wiring layer L9 is formed on each semiconductor substrate S9. Wiring lines H9 that are formed integrally with electrode pads P9, and an interlayer insulating film that insulates the wiring lines H9 from the semiconductor substrate S9 are formed on the wiring layer L9. In this case, the electrode pads P9 are disposed so as to protrude from the sides of the semiconductor substrate S9.

Furthermore, a resin layer J9 is formed on these separated semiconductor substrates S9, and is fixed to the semiconductor substrates S9. Accordingly, the electrode pads P9 protruding from the sides of the semiconductor substrate S9 are supported by the resin layer, and the semiconductor substrates S9 separated into the respective chip regions are integrally supported by the resin layer.

Moreover, it may be possible to cut a semiconductor chip C9 where the resin layer J9 is disposed on the semiconductor substrate S9, by cutting the resin layer J9 along scribe lines B9. In the semiconductor chip C9, the resin layer J9 is disposed so as to protrude from the sides of the semiconductor substrate S9. Further, the electrode pads P9 are disposed so as to protrude from the sides of the semiconductor substrate S9 and are supported below the resin layer J9 that is disposed on the semiconductor substrate S9.

Furthermore, through holes T9, which pass through the resin layer J9 in the vertical direction so that the upper surfaces of the electrode pads P9 are exposed to the outside, are formed at the resin layer J9. Meanwhile, the formation of the through hole T9 may be performed while the separated semiconductor substrates S9 are integrally supported by the resin layer J9.

Further, it may be possible to electrically connect the semiconductor chips C9, which are laminated in the vertical direction, by laminating the semiconductor chips C9 so that the electrode pads P9 overlap each other in the vertical direction, and electrically connecting the upper and lower electrode pads P9 through protruding electrodes 104. Further, it may be possible to mount the laminated semiconductor chips C9 on the mounting substrate U6 by bonding the electrode pads P9 of the lowermost semiconductor chip C9 to the land electrodes 102 through the protruding electrodes 103.

Accordingly, it may be possible to electrically connect the semiconductor chips C9, which are laminated in the vertical direction, without forming openings at the electrode pads P9, to reduce the stress that is applied to the semiconductor substrate S9 or an inorganic insulating film at the time of connecting the semiconductor chips C9, and to prevent cracks from being generated in the semiconductor substrate S9 or the inorganic insulating film.

Meanwhile, in the above-mentioned embodiment, an inorganic insulating film may be laminated below the resin layer J9. In this case, it is preferable that the entire upper surface of the electrode pad P9 be exposed from the inorganic insulating film by forming openings larger than the electrode pads P9 at the inorganic insulating film.

Further, as shown in FIGS. 59A, 59B, and 59C, a resin film J9′ may be laminated on the lower surface of the semiconductor substrate S9. Through holes K9 smaller than the electrode pads P9 are formed at the resin layer J9′, the outer peripheries of the electrode pads P9 are fixed, and a part of the lower surfaces of the electrode pads P9 are exposed to the outside. Furthermore, it may be possible to electrically connect semiconductor chips C9′, which are laminated in the vertical direction, by laminating the semiconductor chips C9′ so that the electrode pads P9 overlap each other in the vertical direction, and electrically connecting the upper and lower electrode pads P9 through protruding electrodes 104′. Moreover, it may be possible to mount the laminated semiconductor chips C9′ on the mounting substrate U6 by bonding the electrode pads P9 of the lowermost semiconductor chip C9′ to the land electrodes 102 through protruding electrodes 103′. In this case, if the resin layer J9′ formed on the lower surface of the semiconductor substrate has thermoplasticity, the resin layer J9′ may be used as an adhesive to laminate the semiconductor chips C9′ and mount the semiconductor chips C9′ on the mounting substrate U6.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate including a wiring layer;
electrode pads that are not provided on, above and below with the semiconductor substrate and are provided to be electrically connected with wiring lines included in the wiring layer; and
a resin layer that is fixed to the semiconductor substrate and supports the electrode pads.

2. The semiconductor device according to claim 1,
wherein the electrode pads and the wiring lines are provided on the same plane.

3. The semiconductor device according to claim 2,
wherein the semiconductor substrate is embedded in the resin layer so that at least a part of the electrode pads are exposed to the outside.

4. The semiconductor device according to claim 3,
wherein the resin layer is provided so as to surround the periphery of the semiconductor substrate.

5. The semiconductor device according to claim 4,
wherein the outer periphery of the resin layer corresponds to scribe lines.

6. A semiconductor device comprising:
a semiconductor substrate including a wiring layer;
electrode pads that are provided so as to protrude laterally from the sides of the semiconductor substrate and are formed to be electrically connected with wiring lines included in the wiring layer; and
resin layers that are fixed to the semiconductor substrate so as to protrude laterally from the sides of the semiconductor substrate and supports the electrode pads; and
through holes or grooves that are provided so as to pass through the electrode pads in a vertical direction, and pass through the resin layers in the vertical direction.

7. The semiconductor device according to claim 6,
wherein the resin layers are provided so as to surround the peripheries of the electrode pads.

8. The semiconductor device according to claim 6,
wherein the resin layers are provided so as to surround the peripheries of the semiconductor substrate.

9. The semiconductor device according to claim 8,
wherein the resin layers are provided so that the electrode pads are interposed between the resin layers in the vertical direction.

10. The semiconductor device according to claim 9,
wherein the outer periphery of the resin layer corresponds to scribe lines.

11. The semiconductor device according to claim 10,
wherein the wiring lines are provided in the wiring layer so that an inorganic insulating film is interposed between the wiring lines and the semiconductor substrate.

12. The semiconductor device according to claim 11,
wherein the inorganic insulating film and the semiconductor substrate are covered with the resin layers.

13. The semiconductor device according to claim 12,
wherein a plurality of semiconductor substrates are laminated in a vertical direction so that the resin layers are interposed between the semiconductor substrates, and includes a conductor embedded in the through holes or grooves so that upper and lower electrode pads are electrically connected to each other.

14. The semiconductor device according to claim 6,
wherein the through hole is formed inside the electrode pad.

15. The semiconductor device according to claim 6,
wherein the through hole is formed to intersect a side of the electrode pad.

16. A method of manufacturing a semiconductor device, the method comprising;
forming a wiring layer, which includes an electrode pad, on a semiconductor substrate of a semiconductor wafer that is divided into chip regions;
forming an inorganic insulating film above the semiconductor wafer;
removing the inorganic insulating film that is formed on the electrode pad and a scribe line of the semiconductor wafer;
forming a first resin layer above the upper surface of the semiconductor wafer, on which the inorganic insulating film is laminated;
forming a first opening through which a part of the upper surface of the electrode pad is exposed from the first resin layer;
removing the semiconductor substrate below the electrode pad by selectively etching the lower surface of the semiconductor substrate;
exposing the electrode pad from a lower surface;
forming a second resin layer on the lower surface of the semiconductor wafer with;
forming a second opening through which a part of the lower surface of the electrode pad is exposed from the second resin layer, and forming a third opening through which the lower surface of the first resin layer corresponding to the scribe line is exposed to the outside; and
cutting the first resin layer and cutting the second resin layer along the scribe line.

17. The method according to claim 16, further comprising:
laminating a plurality of the semiconductor substrates with the first and second resin layers interposed between the semiconductor substrates;
embedding a conductor in the first and second openings so that the upper and lower electrode pads of the plurality of laminated semiconductor substrates are electrically connected to each other.

18. The method according to claim 16, further comprising:
attaching a protective sheet, which supports the semiconductor wafer, to the surface of the semiconductor wafer before the semiconductor substrate is separated into each chip region.

19. The method according to claim 18,
wherein the lower surface of the semiconductor wafer is coated with the second resin layer while the semiconductor substrate is attached to the protective sheet.

20. The method according to claim 17,
wherein the embedding a conductor is electrolytic plating.
